(19) United States
(12) Patent Application Publication
(10) Pub. No.: US 2025/0323064 A1
(43) Pub. Date: Oct. 16, 2025

(54) SUBSTRATE PROCESSING APPARATUS

(71) Applicant: Tokyo Electron Limited, Tokyo (JP)

(72) Inventors: Mikio NAKASHIMA, Kumamoto (JP); Takahiro HAYASHIDA, Kumamoto (JP); Toshifumi NASU, Kumamoto (JP); Shota UMEZAKI, Kumamoto (JP); Atsushi TANAKA, Kumamoto (JP)

(21) Appl. No.: 19/098,397

(22) Filed: Apr. 2, 2025

(30) Foreign Application Priority Data
Apr. 16, 2024 (JP) 2024-066191
Feb. 19, 2025 (JP) 2025-025174

(51) Int. Cl. H01L 21/67

(52) U.S. Cl. CPC H01L 21/67034

(57) ABSTRACT

A substrate processing apparatus according to an aspect of the present disclosure includes a processing device that has a processing space capable of accommodating a substrate whose surface is wet with a liquid, a fluid supply device configured to supply a processing fluid to the processing space, and a controller. The fluid supply device includes a supply line connected to the processing device, a pressurizer provided in the supply line and configured to increase a pressure of the processing fluid flowing through the supply line, a supply flow measurer provided on a secondary side of the pressurizer in the supply line, and a supply flow regulator provided on a secondary side of the supply flow measurer in the supply line. The controller controls the supply flow regulator based on a supply flow rate of the processing fluid measured by the supply flow measurer.

### CROSS-REFERENCE TO RELATED APPLICATIONS

Priority is claimed to Japanese Patent Application No. 2024-066191 filed Apr. 16, 2024 and Japanese Patent Application No. 2025-025174 filed Feb. 19, 2025, the entire content of which is incorporated herein by reference.

### BACKGROUND

### 1. Technical Field

The present disclosure relates to a substrate processing apparatus.

### 2. Description of Related Art

A technique of drying a substrate using a processing fluid in a supercritical state is known. Japanese Unexamined Patent Publication No. 2022-101053 (hereinafter “Patent Document 1”) discloses a configuration in which a flow rate of a processing fluid supplied to a processing container is adjusted by controlling a back pressure regulating valve provided in a circulation line.

### SUMMARY

A substrate processing apparatus according to an aspect of the present disclosure includes a processing device that has a processing space capable of accommodating a substrate whose surface is wet with a liquid, a fluid supply device configured to supply a processing fluid to the processing space, and a controller. The fluid supply device includes a supply line connected to the processing device, a pressurizer provided in the supply line and configured to increase a pressure of the processing fluid flowing through the supply line, a supply flow measurer provided on a secondary side of the pressurizer in the supply line, and a supply flow regulator provided on a secondary side of the supply flow measurer in the supply line. The controller controls the supply flow regulator based on a supply flow rate of the processing fluid measured by the supply flow measurer.

### BRIEF DESCRIPTION OF THE DRAWINGS

FIG. 1 is a block diagram illustrating a substrate processing apparatus according to an embodiment;

FIG. 2 is a diagram illustrating a substrate processing apparatus having a piping configuration according to a first example;

FIG. 3 is a first diagram illustrating operations of the substrate processing apparatus of FIG. 2;

FIG. 4 is a second diagram illustrating operations of the substrate processing apparatus of FIG. 2;

FIG. 5 is a third diagram illustrating operations of the substrate processing apparatus of FIG. 2;

FIG. 6 is a fourth diagram illustrating operations of the substrate processing apparatus of FIG. 2;

FIG. 7 is a fifth diagram illustrating operations of the substrate processing apparatus of FIG. 2;

FIG. 8 is a sixth diagram illustrating operations of the substrate processing apparatus of FIG. 2;

FIG. 9 is a diagram illustrating a substrate processing apparatus having a piping configuration according to a second example;

FIG. 10 is a diagram illustrating a substrate processing apparatus having a piping configuration according to a third example;

FIG. 11 is a first diagram illustrating operations of the substrate processing apparatus of FIG. 10;

FIG. 12 is a second diagram illustrating operations of the substrate processing apparatus of FIG. 10

FIG. 13 is a third diagram illustrating operations of the substrate processing apparatus of FIG. 10;

FIG. 14 is a fourth diagram illustrating operations of the substrate processing apparatus of FIG. 10;

FIG. 15 is a fifth diagram illustrating operations of the substrate processing apparatus of FIG. 10;

FIG. 16 is a sixth diagram illustrating operations of the substrate processing apparatus of FIG. 10;

FIG. 17 is a seventh diagram illustrating operations of the substrate processing apparatus of FIG. 10;

FIG. 18 is a diagram illustrating a substrate processing apparatus having a piping configuration according to a fourth example;

FIG. 19 is a block diagram illustrating a substrate processing apparatus according to a modified example;

FIG. 20 is a first diagram illustrating operations of the substrate processing apparatus of FIG. 19;

FIG. 21 is a second diagram illustrating operations of the substrate processing apparatus of FIG. 19,

FIG. 22 is a third diagram illustrating operations of the substrate processing apparatus of FIG. 19;

FIG. 23 is a fourth diagram illustrating operations of the substrate processing apparatus of FIG. 19;

FIG. 24 is a fifth diagram illustrating operations of the substrate processing apparatus of FIG. 19;

FIG. 25 is a graph showing a relationship between density and pressure in the case where a volume of a processing space is constant; and

FIG. 26 is graphs showing temporal changes in a pressure in the processing space and a mass flow rate of a fluid.

### DETAILED DESCRIPTION

According to the present disclosure, the accuracy of flow rate control of a processing fluid can be improved.

Non-limiting exemplary embodiments of the present disclosure will be described below with reference to the accompanying drawings. In all the accompanying drawings, the same or corresponding members or parts are denoted by the same or corresponding reference numerals, and redundant description will be omitted.

### (Substrate Processing Apparatus)

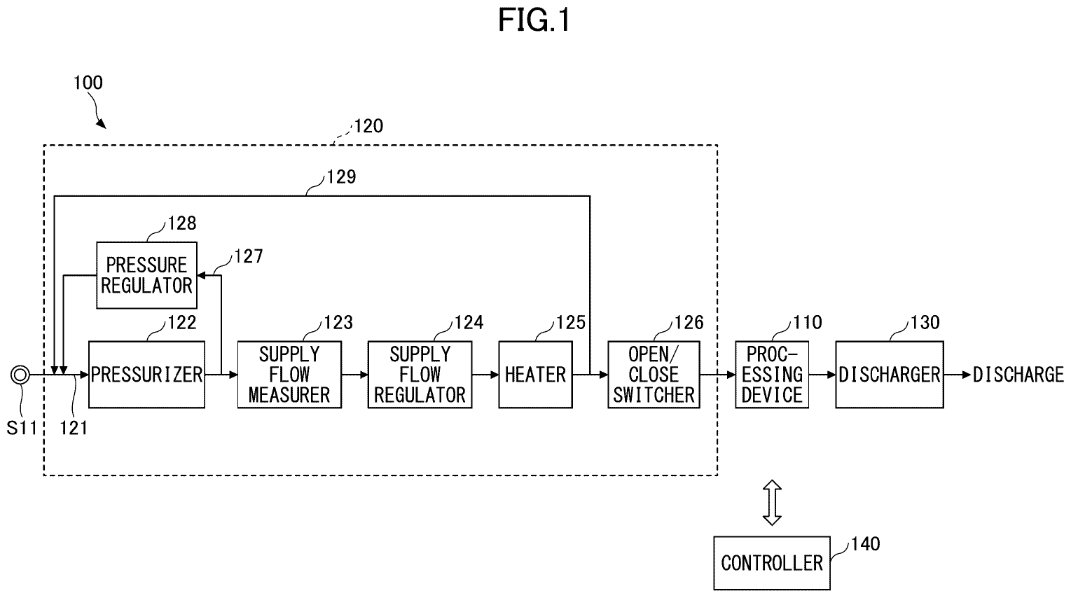

A substrate processing apparatus 100 according to an embodiment will be described with reference to FIG. 1. FIG. 1 is a block diagram illustrating the substrate processing apparatus 100 according to the embodiment.

The substrate processing apparatus 100 includes a processing device 110, a fluid supply device 120, a discharger 130, and a controller 140.

The processing device 110 has a processing space capable of accommodating a substrate whose surface is wet with a liquid. The fluid supply device 120 and the discharger 130 are connected to the processing device 110.

The fluid supply device 120 supplies a processing fluid from a processing fluid supply source S11 to the processing device 110. The fluid supply device 120 includes a supply line 121, a pressurizer 122, a supply flow measurer 123, a supply flow regulator 124, a heater 125, an open/close switcher 126, a first circulator 127, a pressure regulator 128, and a second circulator 129.

The supply line 121 connects the processing fluid supply source S11 and the processing device 110. The supply line 121 supplies the processing fluid from the processing fluid supply source S11 to the processing device 110.

The pressurizer 122 is provided in the supply line 121. The pressurizer 122 increases a pressure of the processing fluid flowing through the supply line 121. The pressurizer 122 is, for example, a pump. The pressurizer 122 may be a pressurizing tank.

The supply flow measurer 123 is provided on the secondary side (i.e., the outlet side) of the pressurizer 122 in the supply line 121. The supply flow measurer 123 measures the supply flow rate of the processing fluid flowing through the supply line 121. The supply flow measurer 123 is, for example, a pressure control type flowmeter. The supply flow measurer 123 may be a mass flowmeter.

The supply flow regulator 124 is provided on the secondary side of the supply flow measurer 123 in the supply line 121. The supply flow regulator 124 regulates a supply flow rate of the processing fluid flowing through the supply line 121 based on a supply flow rate of the processing fluid measured by the supply flow measurer 123. The supply flow regulator 124 includes, for example, a back pressure regulating valve.

The heater 125 is provided on the secondary side of the supply flow regulator 124 in the supply line 121. The heater 125 heats the processing fluid flowing through the supply line 121. The heater 125 is a heating device including a heater, for example.

The open/close switcher 126 is provided on the secondary side of the heater 125 in the supply line 121. The open/close switcher 126 may be provided on the primary side (i.e., the inlet side) of the heater 125 in the supply line 121. The open/close switcher 126 switches on and off the flow of the processing fluid. The open/close switcher 126 allows the processing fluid to flow into the secondary side in an open state, and does not allow the processing fluid to flow into the secondary side in a closed state. The open/close switcher 126 includes, for example, an opening/closing valve.

The first circulator 127 is provided on the primary side of the supply flow regulator 124. The first circulator 127 branches from the supply line 121 at a point between the pressurizer 122 and the supply flow measurer 123, and joins the supply line 121 at a point on the primary side of the pressurizer 122. The first circulator 127 circulates the processing fluid from the secondary side of the pressurizer 122 to the primary side of the pressurizer 122.

The pressure regulator 128 is provided in the first circulator 127. The pressure regulator 128 is provided on the primary side of the supply flow regulator 124. The pressure regulator 128 maintains a pressure on the primary side of the supply flow measurer 123 (and therefore also the supply flow regulator 124) at a set pressure. Thus, a pressure on the primary side of the supply flow regulator 124 can be maintained constant, and thus the accuracy of the flow rate control of the processing fluid supplied to the processing device 11 is improved. The pressure regulator 128 includes, for example, a back pressure regulating valve.

The second circulator 129 branches from the supply line 121 at a point between the heater 125 and the open/close switcher 126, and joins the supply line 121 at a point on the primary side of the pressurizer 122. The second circulator 129 circulates the processing fluid from the secondary side of the heater 125 to the primary side of the pressurizer 122. In the case where the open/close switcher 126 is provided on the primary side of the heater 125, the second circulator 129 may branch from the supply line 121 at a point between the supply flow regulator 124 and the open/close switcher 126, and may join the supply line 121 at a point on the primary side of the pressurizer 122.

The discharger 130 discharges the processing fluid from the processing device 110.

The controller 140 is an electronic circuit such as a central processing unit (CPU), a field programmable gate array (FPGA), or an application specific integrated circuit (ASIC). The controller 140 performs various control operations described in the present specification by executing instruction codes stored in a memory or by designing a circuit for a special purpose.

As described above, according to the substrate processing apparatus 100, the supply flow measurer 123 and the supply flow regulator 124 are provided in series in this order in the supply line 121. Thus, the accuracy of the flow rate control of the processing fluid supplied to the processing device 11 can be improved.

(Substrate Processing Apparatus Having Piping Configuration according to First Example)

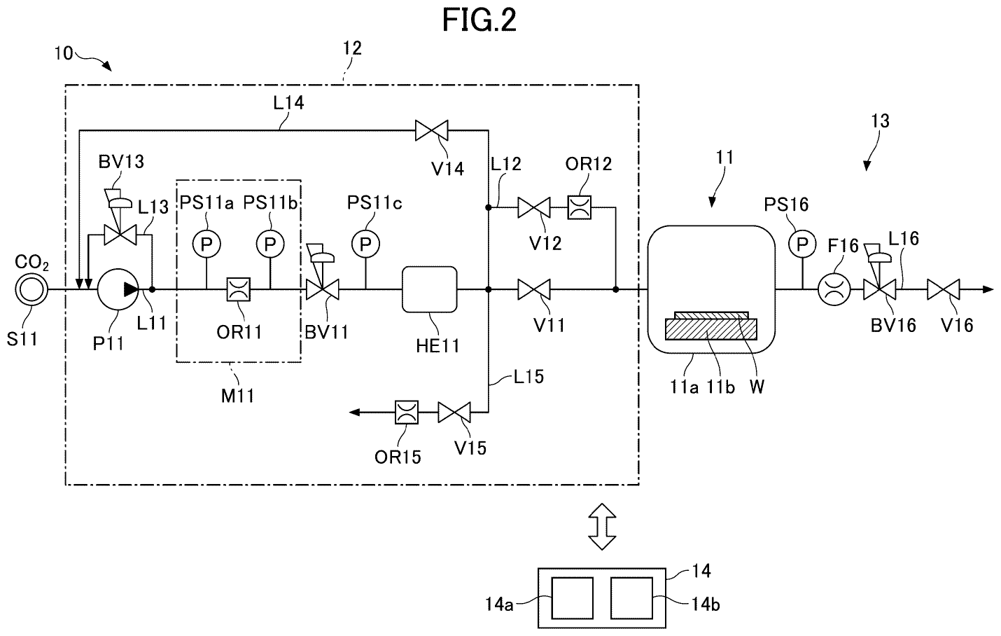

A substrate processing apparatus 10 having a piping configuration according to a first example will be described as an example of the substrate processing apparatus 100 with reference to FIG. 2. FIG. 2 is a diagram illustrating the substrate processing apparatus 10 having a piping configuration according to the first example.

The substrate processing apparatus 10 includes a processing device 11, a fluid supply device 12, a discharger 13, and a controller 14. The processing device 11, the fluid supply device 12, the discharger 13, and the controller 14 correspond to the processing device 110, the fluid supply device 120, the discharger 130, and the controller 140 of FIG. 1, respectively.

The processing device 11 includes a processing vessel 11a and a holder 11b. The processing vessel 11a is a vessel in which a processing space capable of accommodating a substrate W is formed. In the processing space, for example, a substrate on which a liquid film is formed is processed. The substrate W is, for example, a semiconductor wafer. The holder 11b is provided inside the processing vessel 11a. The holder 11b holds the substrate W horizontally. The holder 11b is configured integrally with, for example, the processing vessel 11a. The holder 11b may be a holding plate configured separately from the processing vessel 11a. The processing device 11 may include a temperature sensor and a pressure sensor.

The fluid supply device 12 includes a supply line L11, a branch line L12, a first circulation line L13, a second circulation line L14, and a pressure relief line L15.

The supply line L11 connects the processing fluid supply source S11 and the processing vessel 11a. The supply line L11 supplies the processing fluid from the processing fluid supply source S11 to the processing vessel 11a. The processing fluid is for example carbon dioxide (CO₂) in a gaseous or liquid state. The supply line L11 corresponds to the supply line 121 of FIG. 1. The supply line L11 is provided with a pump P11, a supply flow measurer M11, a back pressure regulating valve BV11, a pressure sensor PS11c, a heater HE11, and an opening/closing valve V11 in this order from the upstream side. A line heater for heating the supply line L11 may be provided in the supply line L11. Opening/closing valves, orifices, filters, temperature sensors, and/or pressures sensors may be further provided at various positions in the supply line L11.

The pump P11 pumps the processing fluid to the secondary side of the supply line L11. The pump P11 corresponds to the pressurizer 122 in FIG. 1.

The supply flow measurer M11 includes a pressure sensor PS11a, an orifice OR11, and a pressure sensor PS11b.

The pressure sensor PS11a is provided on the primary side of the orifice OR11. The pressure sensor PS11a is provided between the pump P11 and the orifice OR11 in the supply line L11. The pressure sensor PS11a measures a pressure on the primary side of the orifice OR11. The pressure sensor PS11a is an example of a first pressure sensor.

The orifice OR11 serves to reduce a flow velocity of and regulate a pressure of the processing fluid flowing through the supply line L11. The orifice OR11 allows the pressure-regulated processing fluid to flow into the secondary side. The orifice OR11 is an example of a first orifice.

The pressure sensor PS11b is provided on the secondary side of the orifice OR11. The pressure sensor PS11b is provided between the orifice OR11 and the back pressure regulating valve BV11 in the supply line L11. The pressure sensor PS11b measures a pressure on the secondary side of the orifice OR11. The pressure sensor PS11b is an example of a second pressure sensor.

The supply flow measurer M11 calculates a supply flow rate of the processing fluid based on a difference between a first pressure P1 measured by the pressure sensor PS11a and a second pressure P2 measured by the pressure sensor PS11b. The processing fluid flowing through the supply flow measurer M11 is, for example, carbon dioxide in a liquid state. In this case, the orifice OR11 is located in a portion where the processing fluid in a liquid state flows. Therefore, the relationship between the flow rate and the differential pressure is a quadratic function, and the supply flow rate of the processing fluid can be measured with high accuracy. Furthermore, the temperature of the processing fluid can be prevented from changing due to adiabatic expansion. The supply flow measurer M11 corresponds to the supply flow measurer 123 of FIG. 1.

The supply flow measurer M11 calculates a supply flow rate Q of the processing fluid flowing through the supply line L11 by, for example, the calculation formula of Expression (1).

$$Q = Cd \cdot {( Δ P )}^{1 / 2} \qquad ( 1 )$$

In Expression (1), ΔP is a value obtained by subtracting the second pressure P2 from the first pressure P1 (ΔP=P1−P2), and Cd is a flow rate coefficient.

The flow rate coefficient Cd can be calculated by the calculation formula of Expression (2) at the time when, for example, the processing fluid is distributed in the processing vessel 11a under a predetermined condition and the first and second pressures P1 and P2 and a discharge flow rate of the processing fluid measured by the flowmeter F16 become stable.

$$Qs = Cd \cdot {( Δ Ps )}^{1 / 2} \qquad ( 2 )$$

In Expression (2), Qs is a discharge flow rate of the processing fluid measured by the flowmeter F16 at the time when the first and second pressures P1 and P2 and a discharge flow rate of the processing fluid measured by the flowmeter F16 become stable. In Expression (2), ΔPs is a differential pressure (ΔPs=P1−P2) between the first pressure P1 and the second pressure P2 at a time point when the first and second pressures P1 and P2 and a discharge flow rate of the processing fluid measured by the flowmeter F16 become stable.

In the case where the pressure on the primary side of the supply line L11 exceeds a set pressure, the back pressure regulating valve BV11 adjusts its opening degree to allow the processing fluid to flow into the secondary side, so that the pressure of the primary side is maintained at the set pressure. The set pressure of the back pressure regulating valve BV11 is regulated based on, for example, a flow rate of the processing fluid measured by the supply flow measurer M11. The set pressure of the back pressure regulating valve BV11 is regulated by the controller 14, for example. The back pressure regulating valve BV11 corresponds to the supply flow regulator 124 in FIG. 1.

The pressure sensor PS11c is provided on the secondary side of the back pressure regulating valve BV11. The pressure sensor PS11c is provided in the supply line L11 between the back pressure regulating valve BV11 and the heater HE11. The pressure sensor PS11c measures a pressure on the secondary side of the BV11.

The heater HE11 is provided on the primary side of the opening/closing valveV11 in the supply line L11. The heater HE11 heats and vaporizes the processing fluid flowing through the supply line L11 and supplies the gas at a predetermined temperature to the secondary side. The predetermined temperature is, for example, 40° C. to 120° C. The heater HE11 corresponds to the heater 125 in FIG. 1.

The opening/closing valve V11 is provided on the secondary side of the heater HE11 in the supply line L11. The opening/closing valve V11 is a valve for switching on and off the flow of the processing fluid. The opening/closing valve V11 allows the processing fluid to flow into the secondary side when in open state, and does not allow the processing fluid to flow into the secondary side when in a closed state. The opening/closing valve V11 corresponds to the open/close switcher 126 in FIG. 1.

The branch line L12 branches from the supply line L11 at a point between the heater HE11 and the opening/closing valve V11, and joins the supply line L11 at a point on the secondary side of the opening/closing valve V11. The branch line L12 supplies the processing fluid vaporized in the heater HE11 to the processing vessel 11a. The branch line L12 is provided with an opening/closing valve V12 and an orifice OR12 in this order from the upstream side.

The opening/closing valve V12 is a valve for switching on and off the flow of the processing fluid. The opening/closing valve V12 allows the processing fluid to flow into the secondary side when in an open state, and does not allow the processing fluid to flow into the secondary side when in a closed state.

The orifice OR12 serves to reduce a flow velocity of and regulate a pressure of the processing fluid flowing through the branch line L12. The orifice OR12 allows the pressure-regulated processing fluid to flow into the secondary side.

The first circulation line L13 branches from the supply line L11 at a point between the pump P11 and the supply flow measurer M11, and joins the supply line L11 at a point on the primary side of the pump P11. The first circulation line L13 circulates the processing fluid from the secondary side of the pump P11 to the primary side of the pump P11. The first circulation line L13 corresponds to the first circulator 127 of FIG. 1. The first circulation line L13 is provided with a back pressure regulating valve BV13. The first circulation line L13 may further include opening/closing valves, orifices, temperature sensors, and/or pressure sensors at various positions.

In the case where the pressure on the secondary side of the pump P11 exceeds a set pressure, the back pressure regulating valve BV13 adjusts its opening degree to allow the processing fluid to flow into the primary side of the pump P11, thereby maintaining the pressure on the secondary side of the pump P11 at the set pressure. The set pressure of the back pressure regulating valve BV13 is regulated by the controller 14, for example. The back pressure regulating valve BV13 corresponds to the pressure regulator 128 in FIG. 1.

The second circulation line L14 branches from the supply line L11 at a point between the heater HE11 and the opening/closing valve V11, and joins the supply line L11 at a point on the primary side of the pump P11. The second circulation line L14 corresponds to the second circulator 129 of FIG. 1. The second circulation line L14 is provided with an opening/closing valve V14. The second circulation line L14 may further include opening/closing valves, orifices, temperature sensors, and/or pressure sensors at various positions.

The opening/closing valve V14 is a valve for switching on and off the flow of the processing fluid. The opening/closing valve V14 allows the processing fluid to flow into the secondary side when in an open state, and does not allow the processing fluid to flow into the secondary side when in a closed state.

The pressure relief line L15 branches from the supply line L11 at a point between the heater HE11 and the opening/closing valve V11. The pressure relief line L15 discharges the processing fluid in the supply line L11. The pressure relief line L15 is provided with an opening/closing valve V15 and an orifice OR15 in this order from the upstream side.

The opening/closing valve V15 is a valve for switching on and off the flow of the processing fluid. The opening/closing valve V15 allows the processing fluid to flow into the secondary side in an open state, and does not allow the processing fluid to flow into the secondary side in a closed state.

The orifice OR15 serves to reduce a flow velocity of and regulate a pressure of the processing fluid flowing through the pressure relief line L15. The orifice OR15 allows the pressure-regulated processing fluid to flow into the secondary side.

The discharger 13 includes a discharge line L16. The discharge line L16 is connected to the processing vessel 11a. The discharge line L16 is provided with a pressure sensor PS16, a flowmeter F16, a back pressure regulating valve BV16, and an opening/closing valve V16 in this order from the upstream side. A line heater for heating the discharge line L16 may be provided in the discharge line L16. The discharge line L16 may further include opening/closing valves, orifices, temperature sensors, and/or pressure sensors at various positions.

The pressure sensor PS16 measures a pressure of the processing fluid flowing through the discharge line L16 immediately after the processing vessel 11a. Thus, the inner pressure of the processing vessel 11a can be measured.

The flowmeter F16 measures a discharge flow rate of the processing fluid flowing through the discharge line L16. An output of the flowmeter F16 is transmitted to the controller 14. The flow meter F16 is, for example, a mass flowmeter.

In the case where the pressure on the primary side of the discharge line L16 exceeds a set pressure, the back pressure regulating valve BV16 adjusts its opening degree to allow the processing fluid to flow into the secondary side, so that the pressure of the primary side is maintained at the set pressure. For example, the set pressure of the back pressure regulating valve BV16 is regulated by the controller 14 based on an output of the pressure sensor PS16.

The opening/closing valve V16 is a valve for switching on and off the flow of the processing fluid. The opening/closing valve V16 allows the processing fluid to flow into the secondary side in an open state, and does not allow the processing fluid to flow into the secondary side in a closed state.

The controller 14 is, for example, a computer. The controller 14 includes an arithmetic calculator 14a and a storage 14b. The storage 14b stores programs for controlling various processes performed in the substrate processing apparatus 10. The arithmetic calculator 14a controls the operations of the substrate processing apparatus 10 by reading and executing the programs stored in the storage 14b. The programs may be recorded in a computer-readable storage media and installed from the storage media to the storage 14b of the controller 14. Examples of the computer-readable storage medium include a hard disk (HD), a flexible disk (FD), a compact disk (CD), a magneto-optical disk (MO), and a memory card.

The controller 14 receives measurement signals from various sensors (e.g., the pressure sensor PS11a, the pressure sensor PS11b, the pressure sensor PS11c, the pressure sensor PS16, and the flowmeter F16), and transmits control signals to various functional elements. The control signals include, for example, opening/closing signals of the opening/closing valves V11, V12, V14, V15, and V16, set pressure signals of the back pressure regulating valves BV11, BV13, and BV16, and a set temperature signal of the heater HE11.

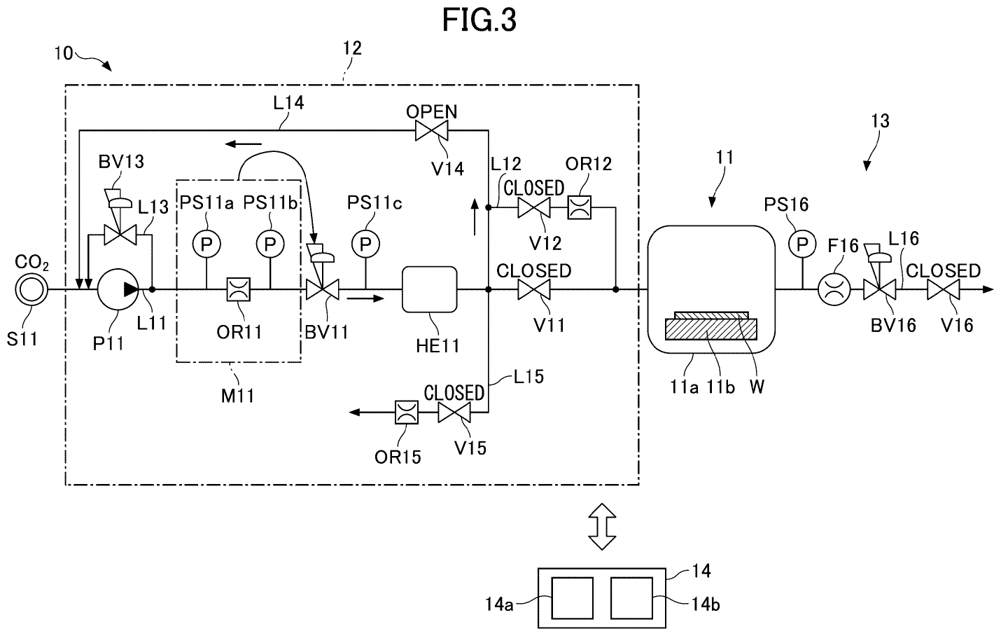

A substrate processing method performed by using the substrate processing apparatus 10 will be described with reference to FIGS. 3 through 8. FIGS. 3 through 8 are diagrams illustrating the operation of the substrate processing apparatus 10 of FIG. 2. The substrate processing method described hereinafter is automatically performed under the control of the controller 14 based on a processing recipe and a control program stored in the storage 14b.

In the description hereinafter, it is assumed that a substrate W is accommodated in the processing vessel 11a in advance. The substrate W subjected to cleaning processing is held by the holder 11b, with the recesses of the pattern on the surface being filled with isopropyl alcohol (IPA).

### <Standby Step>

As illustrated in FIG. 3, in the standby step, the set temperature of the heater HE11 is set to a first temperature, for example, 120° C., the opening/closing valve V14 is set to an opened state, and the opening/closing valves V11, V12, V15, V16 are set to a closed state. Thus, the processing fluid in the processing fluid supply source S11 circulates through the supply line L11, the second circulation line L14, and the supply line L11 in this order. The processing fluid is heated in the heater HE11 in the supply line L11. The processing fluid circulates through the supply line L11, the second circulation line L14, and the supply line L11 in this order, so that the supply line L11 and the second circulation line L14 approach the first temperature. When a predetermined time elapses after the standby step is started, the standby step is ended, and the supply preparation step is started.

During this series of operations, the controller 14 receives the output from the supply flow measurer M11 and regulates the set pressure of the back pressure regulating valve BV11 in such a manner that the supply flow rate of the processing fluid flowing through the primary side of the back pressure regulating valve BV11 becomes a preset flow rate. The output from the supply flow measurer M11 is a supply flow rate of the processing fluid calculated based on, for example, a difference between a first pressure P1 measured by the pressure sensor PS11a and a second pressure P2 measured by the pressure sensor PS11b.

### <Supply Preparation Step>

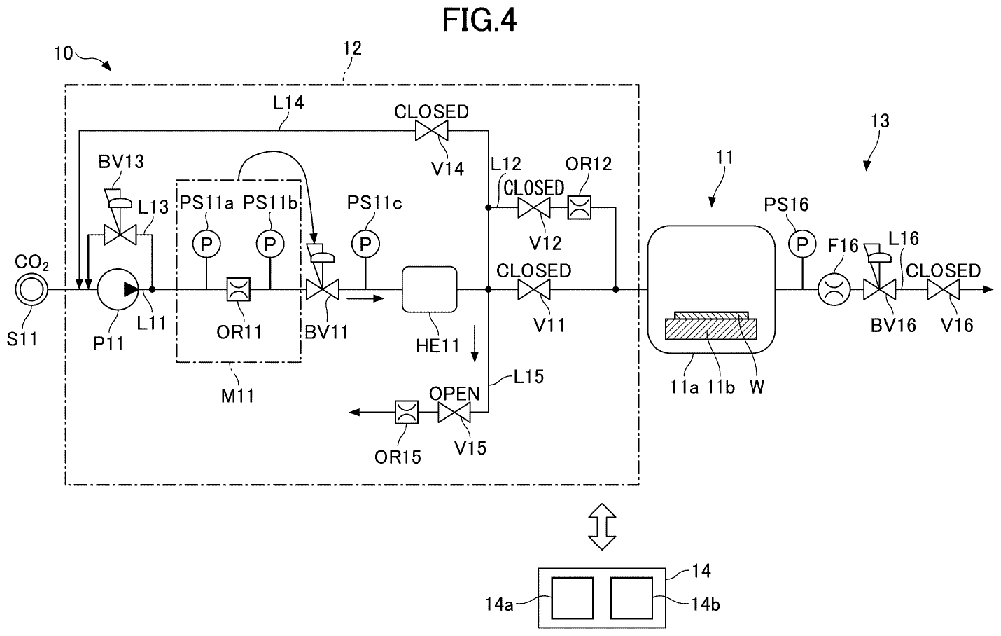

As illustrated in FIG. 4, in the supply preparation step, the opening/closing valve V14 is switched from an open state to a closed state, and the opening/closing valve V15 is switched from a closed state to an open state. Thus, the processing fluid is stopped from circulating through the second circulation line L14, and the processing fluid in the supply line L11 is discharged from the pressure relief line L15. Therefore, the inner pressure of the supply line L11 is decreased. In this case, the high-pressure processing fluid is prevented from being supplied to the processing vessel 11a immediately after the opening/closing valve V12 is opened.

This suppresses the processing fluid from being supplied to the substrate W at a high speed, and pattern collapse can be thereby suppressed. When a predetermined time elapses from the start of the supply preparation step, the supply preparation step is ended, and the first pressure increase step is started.

During this series of operations, the controller 14 receives the output from the supply flow measurer M11 and regulates the set pressure of the back pressure regulating valve BV11 in such a manner that the supply flow rate of the processing fluid flowing through the primary side of the back pressure regulating valve BV11 becomes a preset flow rate. The output from the supply flow measurer M11 is a supply flow rate of the processing fluid calculated based on, for example, a difference between a first pressure P1 measured by the pressure sensor PS11a and a second pressure P2 measured by the pressure sensor PS11b.

### <First Pressure Increase Step>

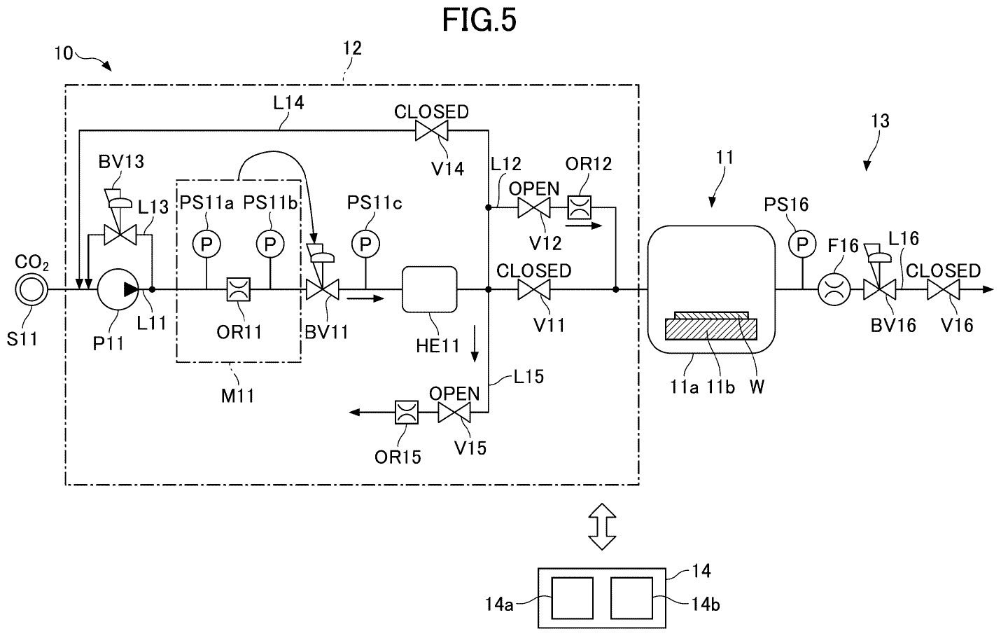

As illustrated in FIG. 5, in the first pressure increase step, the opening/closing valve V12 is switched from a closed state to an open state. Thus, the processing fluid in the processing fluid supply source S11 is heated to the first temperature by the heater HE11 and supplied to the processing vessel 11a via the branch line L12 provided with the opening/closing valve V12. Therefore, the processing fluid at the first temperature is supplied to the processing vessel 11a. In the first pressure increase step, since the opening/closing valve V15 is in an open state, a part of the processing fluid in the processing fluid supply source S11 is discharged from the pressure relief line L15. In the first pressure increase step, the opening/closing valve V16 is in a closed state, and thus the processing fluid does not flow out from the processing vessel 11a. Therefore, the inner pressure of the processing vessel 11a gradually increases. As a result, pattern collapse can be suppressed. When a predetermined time has elapsed after the first pressure increase step is started, the first pressure increase step is ended, and the second pressure increase step is started.

During this series of operations, the controller 14 receives the output from the supply flow measurer M11 and regulates the set pressure of the back pressure regulating valve BV11 in such a manner that the supply flow rate of the processing fluid flowing through the primary side of the back pressure regulating valve BV11 becomes a preset flow rate. The output from the supply flow measurer M11 is a supply flow rate of the processing fluid calculated based on, for example, a difference between a first pressure P1 measured by the pressure sensor PS11a and a second pressure P2 measured by the pressure sensor PS11b.

### <Second Pressure Increase Step>

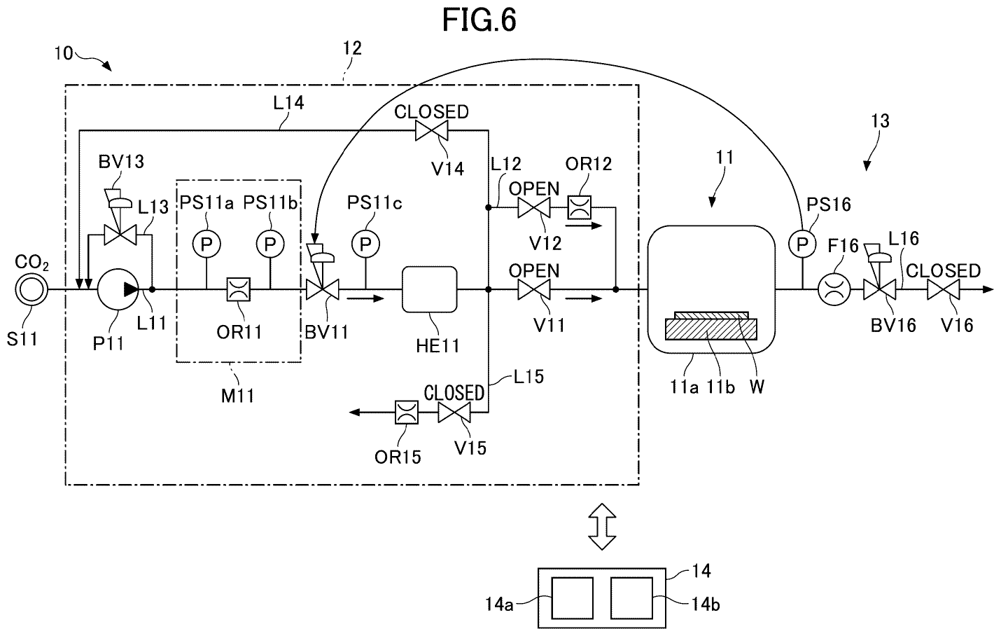

As illustrated in FIG. 6, in the second pressure increase step, the opening/closing valve V15 is switched from an open state to a closed state, and the opening/closing valve V11 is switched from a closed state to an open state. Thus, the processing fluid in the processing fluid supply source S11 is heated to the first temperature by the heater HE11 and supplied to the processing vessel 11a via the supply line L11 provided with the opening/closing valve V11 and the branch line L12 provided with the opening/closing valve V12. Therefore, the processing fluid at the first temperature is supplied to the processing vessel 11a at a flow rate higher than that in the first pressure increase step. In the second pressure increase step, the opening/closing valve V16 is in a closed state, and thus the processing fluid does not flow out from the processing vessel 11a. Therefore, the inner pressure of the processing vessel 11a gradually increases. In the second pressure increase step, since the pressure of the processing fluid having a larger flow rate than that in the first pressure increase step is increased, the pressure increasing speed is higher than that in the first pressure increase step. Therefore, the time required for the pressure increase can be shortened.

In the second pressure increase step, a pressure of the processing fluid supplied to the processing vessel 11a is lower than a critical pressure. Therefore, the processing fluid is supplied to the processing vessel 11a in a gaseous state. Thereafter, the inner pressure of the processing vessel 11a increases as the filling of the processing vessel 11a with the processing fluid proceeds, and when the inner pressure of the processing vessel 11a exceeds a critical inner pressure, the processing fluid present in the processing vessel 11a becomes at a supercritical state. When the inner pressure of the processing vessel 11a reaches the processing pressure, the second pressure increase step is ended and the distribution step is started.

During the series of operations, the controller 14 receives the output from the pressure sensor PS16 and regulates the set pressure of the back pressure regulating valve BV11 in such a manner that the inner pressure of the processing vessel 11a gradually increases at a predetermined rate.

### <Distribution Step>

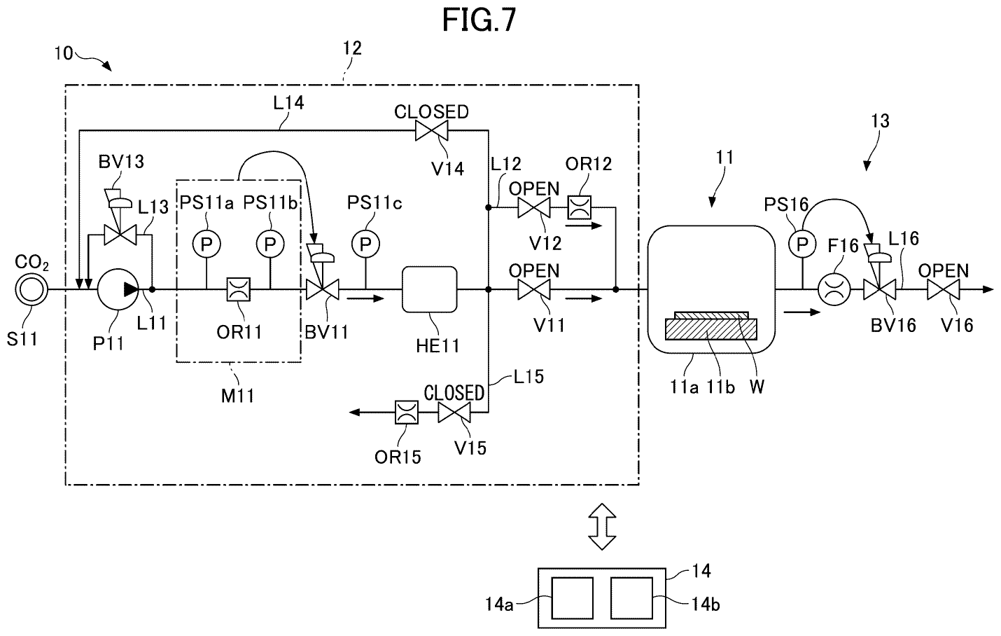

As illustrated in FIG. 7, in the distribution step, the opening/closing valve V16 is switched from a closed state to an open state. Thus, the processing fluid in the processing fluid supply source S11 is supplied to the processing vessel 11a via the supply line L11 provided with the opening/closing valve V11 and the branch line L12 provided with the opening/closing valve V12, and is discharged from the processing vessel 11a via the discharge line L16. In the distribution step, isopropyl alcohol (IPA) in the recesses of the pattern on the substrate W in the processing vessel 11a is replaced with the processing fluid. When the replacement of isopropyl alcohol (IPA) with the processing fluid is completed in the recesses of the pattern, the distribution step is ended and the pressure reduction step is started.

During this series of operations, the controller 14 receives the output from the supply flow measurer M11 and regulates the set pressure of the back pressure regulating valve BV11 in such a manner that the supply flow rate of the processing fluid flowing through the primary side of the back pressure regulating valve BV11 becomes a preset flow rate. The output from the supply flow measurer M11 is a supply flow rate of the processing fluid calculated based on, for example, a difference between a first pressure P1 measured by the pressure sensor PS11a and a second pressure P2 measured by the pressure sensor PS11b.

The controller 14 receives the output from the pressure sensor PS16 and regulates the set pressure of the back pressure regulating valve BV16 so as to maintain the pressure in the processing vessel 11a at the processing pressure.

### <Pressure Reduction Step>

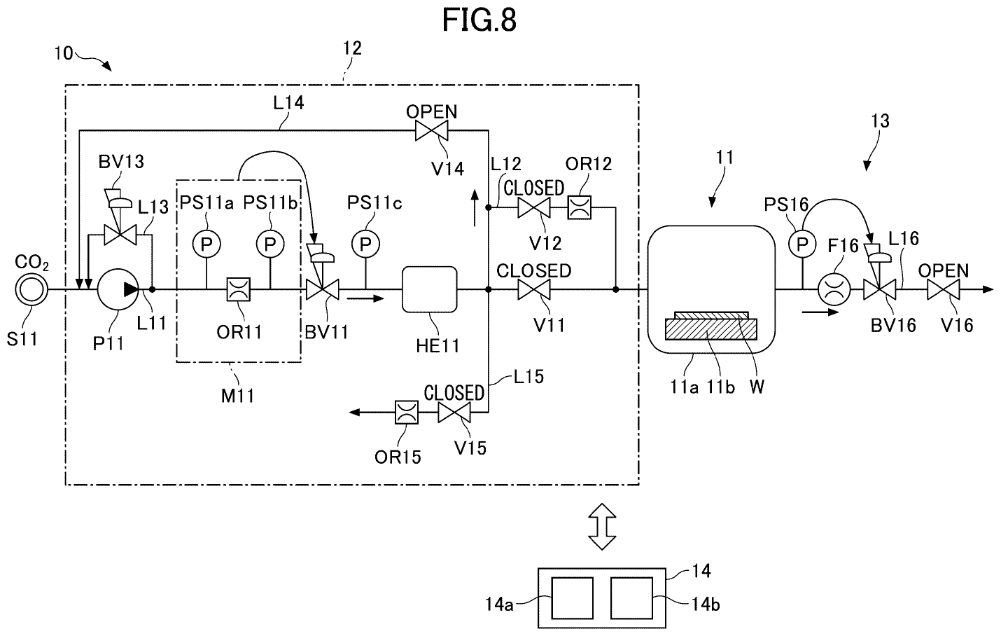

As illustrated in FIG. 8, in the pressure reduction step, the opening/closing valves V11 and V12 are switched from an open state to a closed state. Thus, the processing fluid remaining in the processing vessel 11a is discharged from the discharge line L16. The processing fluid in a supercritical state is vaporized and separated from the surface of the substrate W when the inner pressure of the processing vessel 11a becomes lower than the critical pressure of the processing fluid. Thus, the drying processing for one substrate W is completed. In the pressure reduction step, the opening/closing valve V14 is switched from a closed state to an open state. Thus, the processing fluid in the processing fluid supply source S11 circulates through the supply line L11, the second circulation line L14, and the supply line L11 in this order.

During this series of operations, the controller 14 receives the output from the supply flow measurer M11 and regulates the set pressure of the back pressure regulating valve BV11 in such a manner that the supply flow rate of the processing fluid flowing through the primary side of the back pressure regulating valve BV11 becomes a preset flow rate. The output from the supply flow measurer M11 is a supply flow rate of the processing fluid calculated based on, for example, a difference between a first pressure P1 measured by the pressure sensor PS11a and a second pressure P2 measured by the pressure sensor PS11b.

The controller 14 receives the output from the pressure sensor PS16 and regulates the set pressure of the back pressure regulating valve BV16 in such a manner that the inner pressure of the processing vessel 11a gradually changes at a predetermined rate.

As described above, according to the substrate processing apparatus 10, the supply flow measurer M11 and the back pressure regulating valve BV11 are provided in series in this order in the supply line L11. Thus, the accuracy of the flow rate control of the processing fluid supplied to the processing device 11 can be improved.

According to the substrate processing apparatus 10, the primary side and the secondary side of the back pressure regulating valve BV11 are always filled with the processing fluid in a liquid state. Therefore, a difference in pressure is unlikely to occur inside the back pressure regulating valve BV11. As a result, the generation of particles can be reduced.

According to the substrate processing apparatus 10, since the primary side of the back pressure regulating valve BV11 is always pressurized in the standby step, the supply preparation step, the first pressure increase step, the second pressure increase step, the distribution step, and the pressure reduction step, the processing fluid can be thereby supplied to the secondary side. Therefore, the seal portion of the back pressure regulating valve BV11 can be prevented from biting into the groove. As a result, the initial operation of the back pressure regulating valve BV11 is improved.

(Substrate Processing Apparatus Having Piping Configuration according to Second Example)

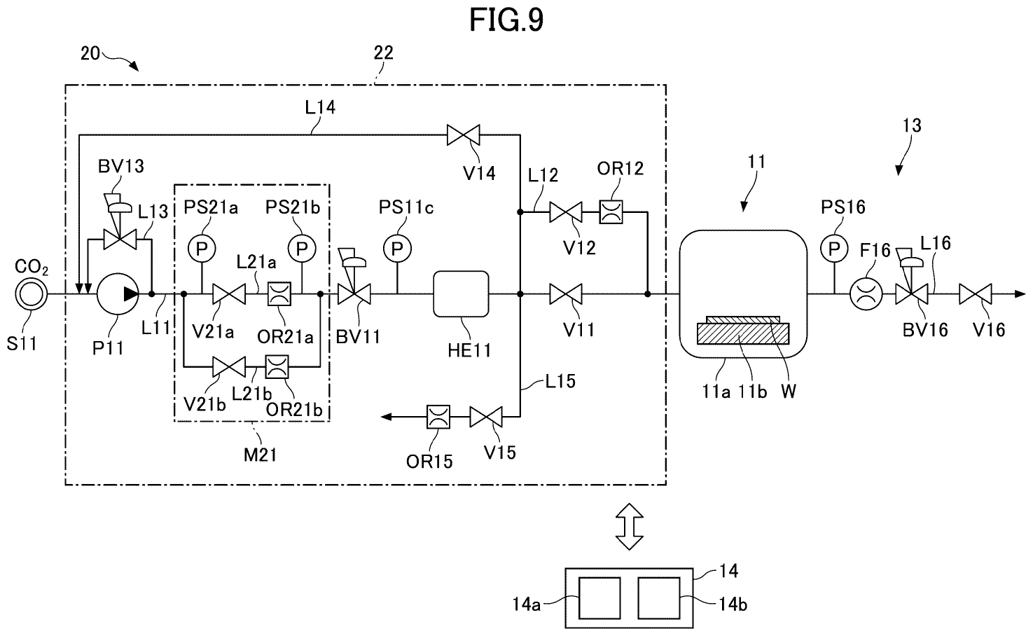

A substrate processing apparatus 20 having a piping configuration according to a second example will be described as an example of the substrate processing apparatus 100 with reference to FIG. 9. FIG. 9 is a diagram illustrating the substrate processing apparatus 20 having a piping configuration according to the second example.

The substrate processing apparatus 20 differs from the substrate processing apparatus 10 in that the fluid supply device 22 is provided instead of the fluid supply device 12. The other configurations may be the same as those of the substrate processing apparatus 10. Hereinafter, a configuration different from the substrate processing apparatus 10 will be mainly described.

The fluid supply device 22 includes the supply line L11, the branch line L12, the first circulation line L13, the second circulation line L14, and the pressure relief line L15.

The supply line L11 is provided with the pump P11, the supply flow measurer M21, the back pressure regulating valve BV11, the pressure sensor PS11c, the heater HE11, and the opening/closing valve V11 in this order from the upstream side.

The supply flow measurer M21 includes a first supply line L21a and a second supply line L21b.

The first supply line L21a is a part of the supply line L11. The first supply line L21a is provided with a pressure sensor PS21a, an opening/closing valve V21a, an orifice OR21a, and a pressure sensor PS21b in this order from the upstream side.

The pressure sensor PS21a and the pressure sensor PS21b may have the same configuration as the pressure sensor PS11a and the pressure sensor PS11b, respectively.

The opening/closing valve V21a is a valve for switching on and off the flow of the processing fluid. The opening/closing valve V21a allows a processing fluid to flow into the secondary side in an open state, and does not allow a processing fluid to flow into the secondary side in a closed state.

The orifice OR21a serves to reduce a flow velocity of and regulate a pressure of the processing fluid flowing through the first supply line L21a. The orifice OR21a allows the pressure-regulated processing fluid to flow into the secondary side. The orifice OR21a is an example of a first orifice.

The second supply line L21b is provided in parallel with the first supply line L21a. The second supply line L21b branches off from the first supply line L21a at a point between the pump P11 and the pressure sensor PS21a, and joins the first supply line L21a at a point between the pressure sensor PS21b and the back pressure regulating valve BV11. The second supply line L21b is provided with an opening/closing valve V21b and an orifice OR21b in this order from the upstream side.

The opening/closing valve V21b is provided in parallel with the opening/closing valve V21a. The opening/closing valve V21b is a valve for switching on and off the flow of the processing fluid. The opening/closing valve V21b allows the processing fluid to flow into the secondary side in an open state, and does not allow the processing fluid to flow into the secondary side in a closed state.

The orifice OR21b is provided in parallel with the orifice OR21a. The orifice OR21b serves to reduce a flow velocity of and regulate a pressure of the processing fluid flowing through the second supply line L21b. The orifice OR21b allows the pressure-regulated processing fluid to flow into the secondary side. The orifice OR21b is an example of a second orifice.

As described above, the substrate processing apparatus 20 provides the same effects as the substrate processing apparatus 10.

According to the substrate processing apparatus 20, the second supply line L21b is provided in parallel to the first supply line L21a. The first supply line L21a is provided with the opening/closing valve V21a and the orifice OR21a, and the second supply line L21b is provided with the opening/closing valve V21b and an orifice OR21b. In this case, the regulation range of the supply flow rate of the processing fluid can be increased.

(Substrate Processing Apparatus Having Piping Configuration according to Third Example)

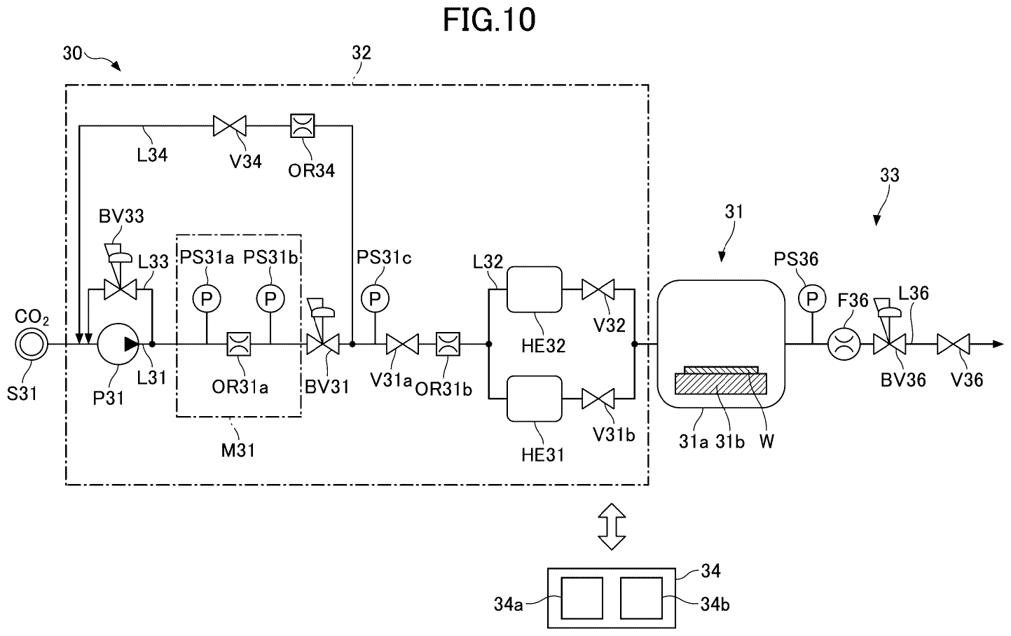

A substrate processing apparatus 30 having a piping configuration according to a third example will be described as an example of the substrate processing apparatus 100 with reference to FIG. 10. FIG. 10 is a diagram illustrating the substrate processing apparatus 30 having a piping configuration according to the third example.

The substrate processing apparatus 30 includes a processing device 31, a fluid supply device 32, a discharger 33, and a controller 34. The processing device 31, the fluid supply device 32, the discharger 33, and the controller 34 correspond to the processing device 110, the fluid supply device 120, the discharger 130, and the controller 140 of FIG. 1, respectively.

The processing device 31 may have the same configuration as the processing device 11. The processing device 31 includes a processing vessel 31a and a holder 31b.

The fluid supply device 32 includes a supply line L31, a branch line L32, a first circulation line L33, and a second circulation line L34.

The supply line L31 connects the processing fluid supply source S31 and the processing vessel 31a. The supply line L31 supplies a processing fluid from the processing fluid supply source S31 to the processing vessel 31a. The processing fluid is for example carbon dioxide in a gaseous or liquid state. The supply line L31 corresponds to the supply line 121 of FIG. 1. The supply line L31 is provided with a pump P31, a supply flow measurer M31, a back pressure regulating valve BV31, a pressure sensor PS31c, an opening/closing valve V31a, an orifice OR31b, a heater HE31, and an opening/closing valve V31b in this order from the upstream side. A line heater for heating the supply line L31 may be provided in the supply line L31. Opening/closing valves, orifices, filters, temperature sensors, and/or pressures sensors may be further provided at various positions of the supply line L31.

The pump P31 may be configured similarly to the pump P11. The pump P31 corresponds to the pressurizer 122 in FIG. 1.

The supply flow measurer M31 may have the same configuration as the supply flow measurer M11. The supply flow measurer M31 includes a pressure sensor PS31a, an orifice OR31a, and a pressure sensor PS31b. The pressure sensor PS31a is an example of a first pressure sensor. The orifice OR31a is an example of a first orifice. The pressure sensor PS31b is an example of a second pressure sensor. The supply flow measurer M31 corresponds to the supply flow measurer 123 of FIG. 1.

The back pressure regulating valve BV31 may have the same configuration as the back pressure regulating valve BV11. The back pressure regulating valve BV31 corresponds to the supply flow regulator 124 in FIG. 1. The pressure sensor PS31c is provided on the secondary side of the back pressure regulating valve BV31. The pressure sensor PS31c is provided between the back pressure regulating valve BV31 and the opening/closing valve V31a in the supply line L31. The pressure sensor PS31c measures a pressure on the secondary side of the BV31.

The opening/closing valve V31a is provided on the primary side of the heater H31 in the supply line L31. The opening/closing valve V31a is a valve for switching on and off the flow of the processing fluid. The opening/closing valve V31a allows the processing fluid to flow into the secondary side in an open state, and does not allow the processing fluid to flow into the secondary side in a closed state. The opening/closing valve V31 corresponds to the open/close switcher 126 in FIG. 1.

The orifice OR31b serves to reduce a flow velocity of and regulate a pressure of the processing fluid flowing through the supply line L31. The orifice OR31b allows the pressure-regulated processing fluid to flow into the secondary side.

The heater HE31 is provided on the secondary side of the opening/closing valve V31a in the supply line L31. The heater HE31 heats and vaporizes the processing fluid flowing through the supply line L31 and supplies the gas at a first temperature to the secondary side. The first temperature may be 40° C. to 90° C. The first temperature is, for example, 80° C. The heater HE31 corresponds to the heater 125 in FIG. 1.

The opening/closing valve V31b is provided on the primary side of the heater H31 in the supply line L31. The opening/closing valve V31b is a valve for switching on and off the flow of the processing fluid. The opening/closing valve V31b allows the processing fluid to flow into the secondary side in an open state, and does not allow the processing fluid to flow into the secondary side in a closed state.

The branch line L32 branches from the supply line L31 at a point between the orifice OR31b and the heater HE31, and joins the supply line L31 at a point on the secondary side of the opening/closing valve V31b. The branch line L32 is provided with a heater HE32 and an opening/closing valve V32 in this order from the upstream side.

The heater HE32 is provided in parallel with the heater HE31. The heater HE32 heats and vaporizes the processing fluid flowing through the branch line L32 and supplies the gas at a second temperature to the secondary side. The second temperature is higher than the first temperature. The second temperature may be 100° C. to 120° C. The second temperature is, for example, 120° C. The heater HE32 corresponds to the heater 125 in FIG. 1.

The opening/closing valve V32 is a valve for switching on and off the flow of the processing fluid. The opening/closing valve V32 allows the processing fluid to flow into the secondary side in an open state, and does not allow the processing fluid to flow into the secondary side in a closed state.

The first circulation line L33 may have the same configuration as the first circulation line L13. The first circulation line L33 corresponds to the first circulator 127 of FIG. 1. The first circulation line L33 is provided with a back pressure regulating valve BV33. The first circulation line L33 may further include opening/closing valves, orifices, temperature sensors, and/or pressure sensors at various positions.

The back pressure regulating valve BV33 may have the same configuration as the back pressure regulating valve BV13. The back pressure regulating valve BV33 corresponds to the pressure regulator 128 in FIG. 1.

The second circulation line L34 branches from the supply line L31 at a point between the back pressure regulating valve BV31 and the opening/closing valve V31a, and joins the supply line L31 at a point on the primary side of the pump P31. The second circulation line L34 corresponds to the second circulator 129 of FIG. 1. The second circulation line L34 is provided with an orifice OR34 and an opening/closing valve V34 in this order from the upstream side. The second circulation line L34 may further include opening/closing valves, orifices, temperature sensors, and/or pressure sensors at various positions.

The orifice OR34 serves to reduce a flow velocity of and regulate a pressure of the processing fluid flowing through the second circulation line L34. The orifice OR34 allows the pressure-regulated processing fluid to flow into the secondary side.

The opening/closing valve V34 is a valve for switching on and off the flow of the processing fluid. The opening/closing valve V34 allows the processing fluid to flow into the secondary side in an open state, and does not allow the processing fluid to flow into the secondary side in a closed state.

The discharger 33 may have the same configuration as the discharger 13. The discharger 33 includes a discharge line L36. The discharge line L36 is provided with a pressure sensor PS36, a flowmeter F36, a back pressure regulating valve BV36, and an opening/closing valve V36 in this order from the upstream side.

The controller 34 may have the same configuration as the controller 14. The controller 34 includes an arithmetic calculator 34a and a storage 34b.

The controller 34 receives measurement signals from various sensors (e.g., the pressure sensor PS31a, the pressure sensor PS31b, the pressure sensor PS31c, the pressure sensor PS36, and the flowmeter F36), and transmits control signals to various functional elements. The control signals include, for example, opening/closing signals of the opening/closing valves V31a, V31b, V32, V34, and V36, set pressure signals of the back pressure regulating valves BV31, BV33, and BV36, and a set temperature signal of the heaters HE31 and HE32.

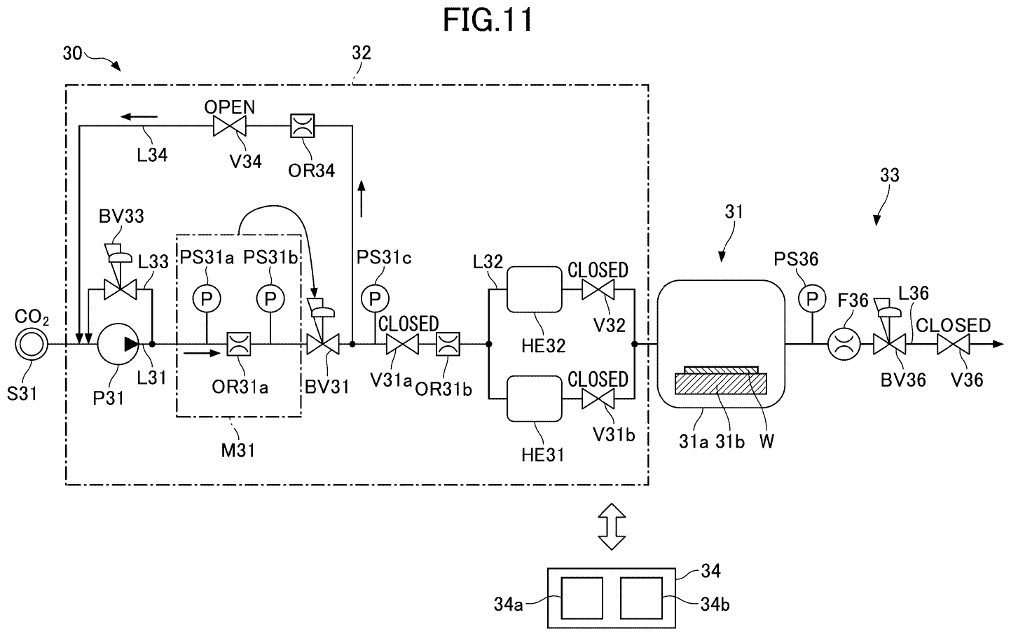

A substrate processing method performed by using the substrate processing apparatus 30 will be described with reference to FIGS. 11 through 17. FIGS. 11 through 17 are diagrams illustrating the operation of the substrate processing apparatus 30 of FIG. 10. The substrate processing method described hereinafter is automatically performed under the control of the controller 34 based on a processing recipe and a control program stored in the storage 34b.

In the description hereinafter, it is assumed that a substrate W is accommodated in the processing vessel 31a in advance. The substrate W subjected to cleaning processing is held by the holder 31b, with the recesses of the pattern on the surface being filled with isopropyl alcohol (IPA).

### <Standby Step>

As illustrated in FIG. 11, in the standby step, the preset temperature of the heater HE31 is set to the first temperature, for example, 80° C., and the preset temperature of the heater HE32 is set to the second temperature, for example, 120° C. The opening/closing valve V34 is set to an open state, and the opening/closing valves V31a, V31b, V32, and V36 are set to a closed state. Thus, the processing fluid in the processing fluid supply source S31 circulates through the supply line L31, the second circulation line L34, and the supply line L31 in this order. When a predetermined time elapses after the standby step is started, the standby step is ended, and the supply preparation step is started.

During this series of operations, the controller 34 receives the output from the supply flow measurer M31 and regulates the set pressure of the back pressure regulating valve BV31 in such a manner that the supply flow rate of the processing fluid flowing through the primary side of the back pressure regulating valve BV31 becomes a preset flow rate. The output from the supply flow measurer M31 is a supply flow rate of the processing fluid calculated based on, for example, a difference between a first pressure P1 measured by the pressure sensor PS31a and a second pressure P2 measured by the pressure sensor PS31b.

### <Supply Preparation Step>

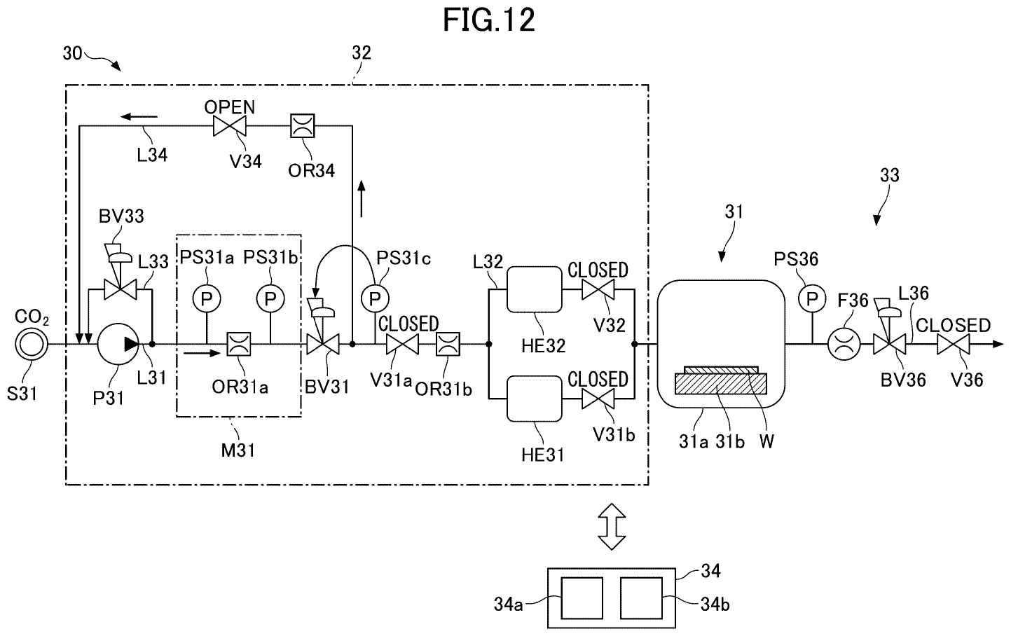

As illustrated in FIG. 12, in the supply preparation step, the opening/closing valve V34 is maintained in an open state, and the opening/closing valves V31a, V31b, V32, and V36 are maintained in a closed state. When a predetermined time elapses from the start of the supply preparation step, the supply preparation step is ended, and the first pressure increase step is started.

During this series of operations, the controller 34 receives the output from the back pressure sensor PS31c and regulates the set pressure of the back pressure regulating valve BV31 in such a manner that the secondary side of the back pressure regulating valve BV31 is at a preset pressure.

### <First Pressure Increase Step>

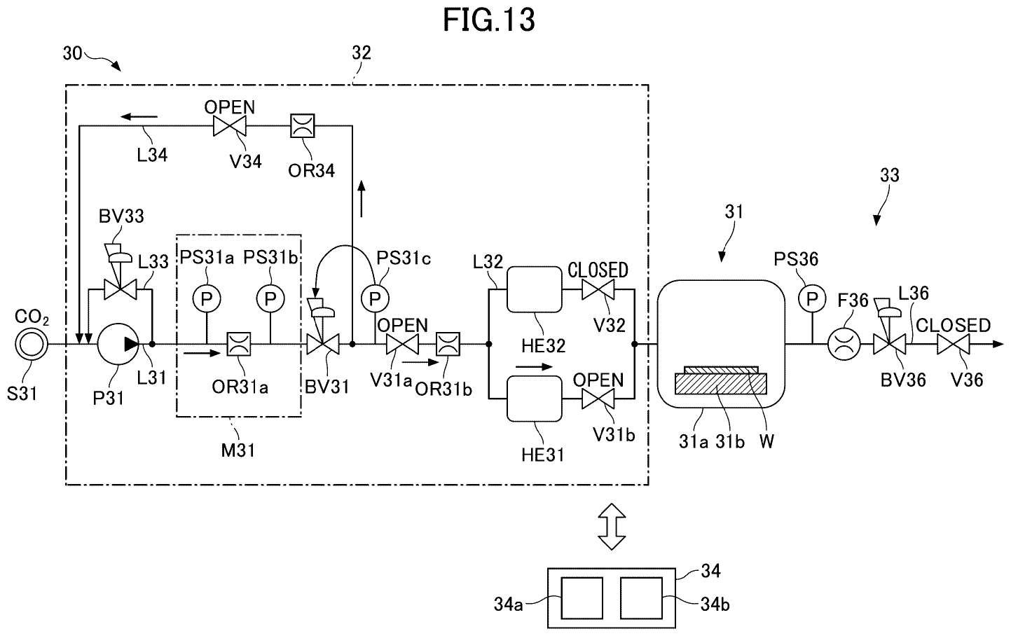

As illustrated in FIG. 13, in the first pressure increase step, the opening/closing valves V31a and V31b are switched from a closed state to an open state. Thus, the processing fluid in the processing fluid supply source S31 is heated to the first temperature by the heater HE31 and supplied to the processing vessel 31a. In the first pressure increase step, since the opening/closing valve V34 is in an open state, a part of the processing fluid in the processing fluid supply source S31 is returned to the primary side of the pump P31 in the supply line L31 via the second circulation line L34. In the first pressure increase step, the opening/closing valve V36 is in a closed state, and thus the processing fluid does not flow out from the processing vessel 31a. Therefore, the inner pressure of the processing vessel 31a gradually increases. As a result, pattern collapse can be suppressed. When a predetermined time has elapsed after the first pressure increase step is started, the first pressure increase step is ended, and the second pressure increase step is started.

During this series of operations, the controller 34 receives the output from the back pressure sensor PS31c and regulates the set pressure of the back pressure regulating valve BV31 in such a manner that the secondary side of the back pressure regulating valve BV31 is at a preset pressure.

### <Second Pressure Increase Step>

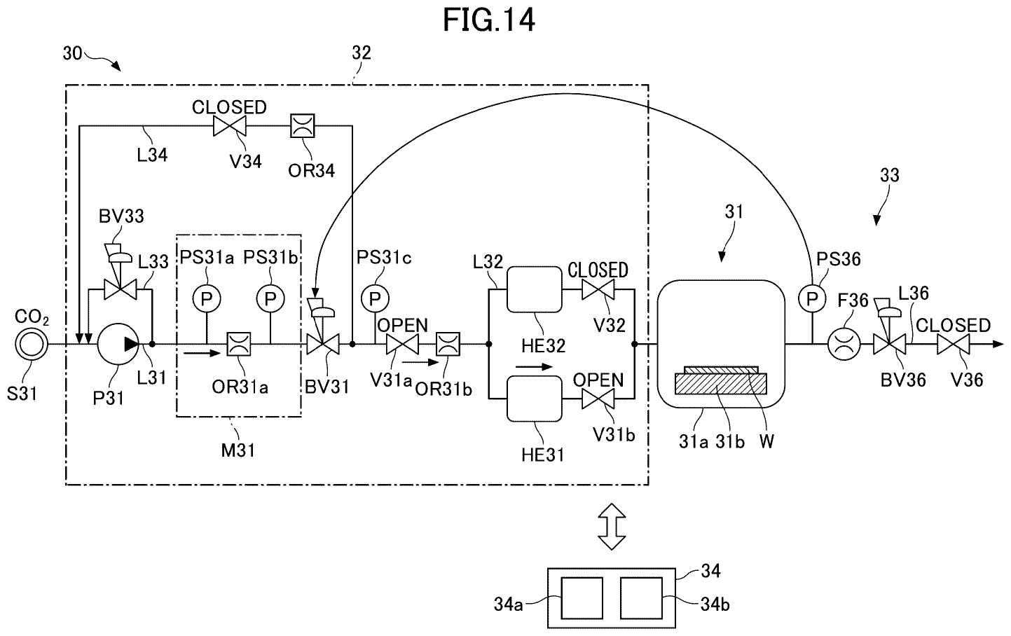

As illustrated in FIG. 14, in the second pressure increase step, the opening/closing valve V34 is switched from an open state to a closed state. Thus, the processing fluid in the processing fluid supply source S31 is heated to the first temperature by the heater HE31 and supplied to the processing vessel 31a. In the second pressure increase step, the opening/closing valve V36 is in a closed state, and thus the processing fluid does not flow out from the processing vessel 31a. Therefore, the inner pressure of the processing vessel 31a gradually increases. In the second pressure increase step, the opening/closing valve V34 is in a closed state, and thus the processing fluid in the processing fluid supply source S31 does not flow out to the second circulation line L34. Therefore, since the pressure of the processing fluid having a larger flow rate than that in the first pressure increase step is increased, the pressure increasing speed can be increased. When a predetermined time has elapsed after the second pressure increase step is started, the third pressure increase step is started.

During the series of operations, the controller 34 receives the output from the pressure sensor PS36 and regulates the set pressure of the back pressure regulating valve BV31 in such a manner that the inner pressure of the processing vessel 31a gradually increases at a predetermined rate.

### <Third Pressure Increase Step>

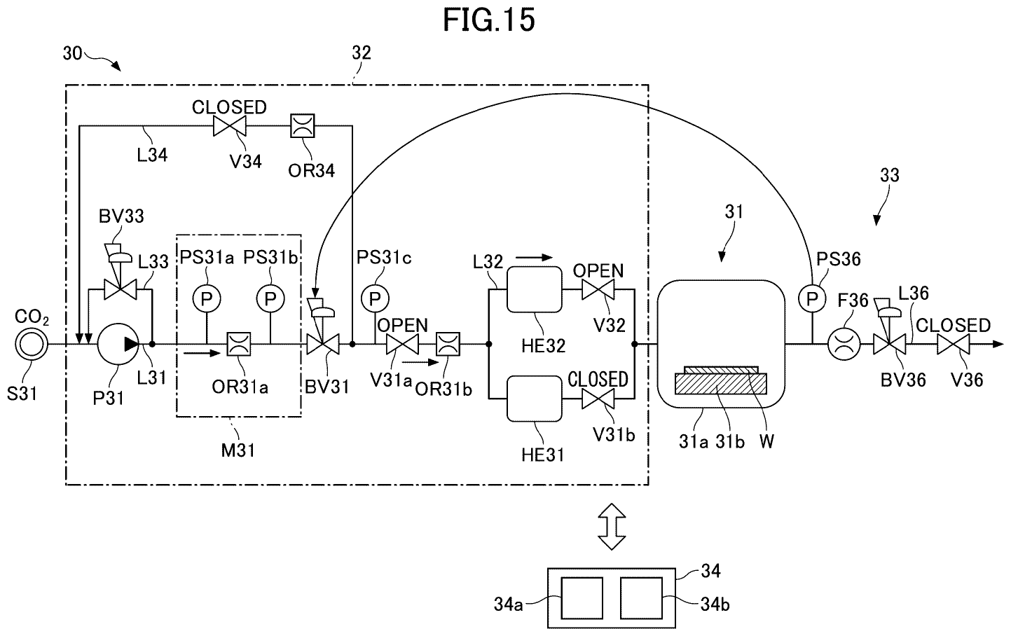

As illustrated in FIG. 15, in the third pressure increase step, the opening/closing valve V31b is switched from an open state to a closed state, and the opening/closing valve V32 is switched from a closed state to an open state. Thus, the processing fluid in the processing fluid supply source S31 is heated to the second temperature by the heater HE32 and supplied to the processing vessel 31a. In the third pressure increase step, the opening/closing valve V36 is in a closed state, and thus the processing fluid does not flow out from the processing vessel 31a. Therefore, the inner pressure of the processing vessel 31a gradually increases. In the third pressure increase step, the opening/closing valve V34 is in a closed state, and thus the processing fluid in the processing fluid supply source S31 does not flow out to the second circulation line L34. Therefore, since the pressure of the processing fluid having a larger flow rate than that in the first pressure increase step is increased, the pressure increasing speed can be increased.

In the third pressure increase step, a pressure of the processing fluid supplied to the processing vessel 31a is lower than a critical pressure. Therefore, the processing fluid is supplied to the processing vessel 31a in a gaseous state. Thereafter, the inner pressure of the processing vessel 31a increases as the filling of the processing vessel 31a with the processing fluid proceeds, and when the inner pressure of the processing vessel 31a exceeds a critical inner pressure, the processing fluid present in the processing vessel 31a becomes at a supercritical state. When the inner pressure of the processing vessel 31a reaches the processing pressure, the third pressure increase step is ended and the distribution step is started.

During the series of operations, the controller 34 receives the output from the pressure sensor PS36 and regulates the set pressure of the back pressure regulating valve BV31 in such a manner that the inner pressure of the processing vessel 31a gradually increases at a predetermined rate.

### <Distribution Step>

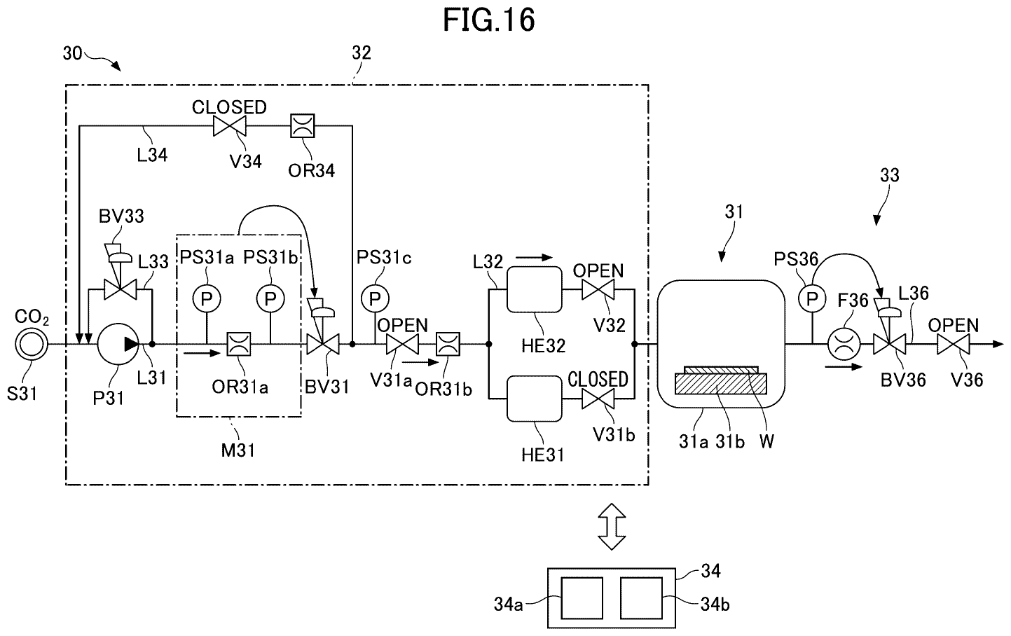

As illustrated in FIG. 16, in the distribution step, the opening/closing valve V36 is switched from a closed state to an open state. Thus, the processing fluid in the processing fluid supply source S31 is heated to the second temperature by the heater HE32, supplied to the processing vessel 31a, and discharged from the processing vessel 31a via the discharge line L36. In the distribution step, isopropyl alcohol (IPA) in the recesses of the pattern on the substrate W in the processing vessel 31a is replaced with the processing fluid. When the replacement of isopropyl alcohol (IPA) with the processing fluid is completed in the recesses of the pattern, the distribution step is ended and the pressure reduction step is started.

During this series of operations, the controller 34 receives the output from the supply flow measurer M31 and regulates the set pressure of the back pressure regulating valve BV31 in such a manner that the supply flow rate of the processing fluid flowing through the primary side of the back pressure regulating valve BV31 becomes a preset flow rate. The output from the supply flow measurer M31 is a supply flow rate of the processing fluid calculated based on, for example, a difference between a first pressure P1 measured by the pressure sensor PS31a and a second pressure P2 measured by the pressure sensor PS31b.

The controller 34 receives the output from the pressure sensor PS36 and regulates the set pressure of the back pressure regulating valve BV36 so as to maintain the pressure in the processing vessel 31a at the processing pressure.

### <Pressure Reduction Step>

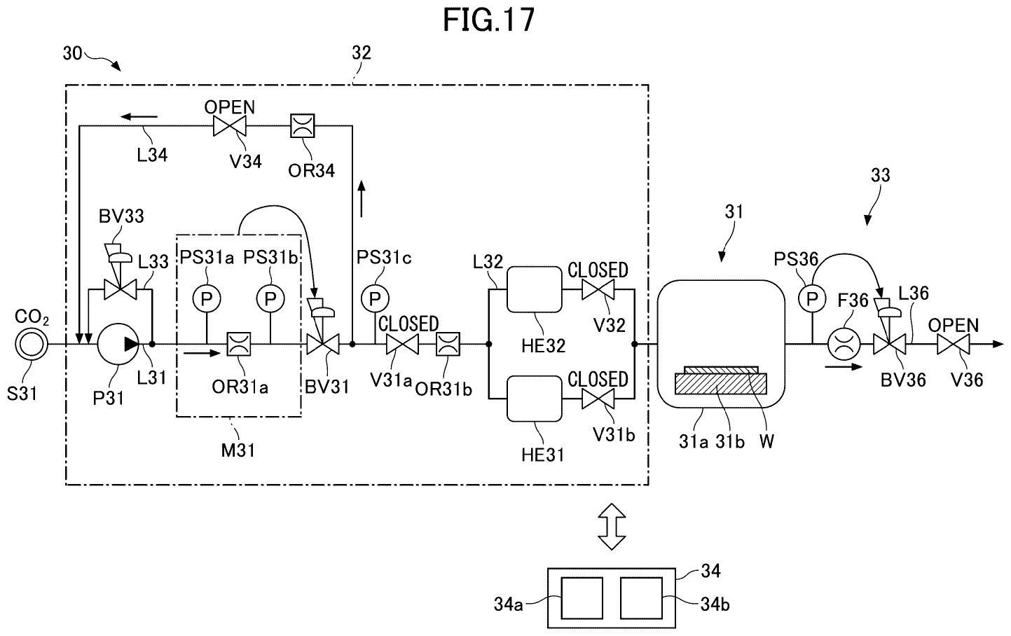

As illustrated in FIG. 17, in the pressure reduction step, the opening/closing valves V31a and V32 are switched from an open state to a closed state. Thus, the processing fluid remaining in the processing vessel 31a is discharged from the discharge line L36. The processing fluid in a supercritical state is vaporized and separated from the surface of the substrate W when the inner pressure of the processing vessel 31a becomes lower than the critical pressure of the processing fluid. Thus, the drying processing for one substrate W is completed. In the pressure reduction step, the opening/closing valve V34 is switched from a closed state to an open state. Thus, the processing fluid in the processing fluid supply source S31 circulates through the supply line L31, the second circulation line L34, and the supply line L31 in this order.

During this series of operations, the controller 34 receives the output from the supply flow measurer M31 and regulates the set pressure of the back pressure regulating valve BV31 in such a manner that the supply flow rate of the processing fluid flowing through the primary side of the back pressure regulating valve BV31 becomes a preset flow rate. The output from the supply flow measurer M31 is a supply flow rate of the processing fluid calculated based on, for example, a difference between a first pressure P1 measured by the pressure sensor PS31a and a second pressure P2 measured by the pressure sensor PS31b.

The controller 34 receives the output from the pressure sensor PS36 and regulates the set pressure of the back pressure regulating valve BV36 in such a manner that the inner pressure of the processing vessel 31a gradually changes at a predetermined rate.

As described above, according to the substrate processing apparatus 30, the supply flow measurer M31 and the back pressure regulating valve BV31 are provided in series in this order in the supply line L31. Thus, the accuracy of the flow rate control of the processing fluid supplied to the processing device 31 can be improved.

According to the substrate processing apparatus 30, the primary side and the secondary side of the back pressure regulating valve BV31 are always filled with the processing fluid in a liquid state. Therefore, a difference in pressure is unlikely to occur inside the back pressure regulating valve BV31. As a result, the generation of particles can be reduced.

According to the substrate processing apparatus 30, since the primary side of the back pressure regulating valve BV31 is always pressurized in the standby step, the supply preparation step, the first pressure increase step, the second pressure increase step, the third pressure increase step, the distribution step, and the pressure reduction step, the processing fluid can be thereby supplied to the secondary side. Therefore, the seal portion of the back pressure regulating valve BV31 can be prevented from biting into the groove. As a result, the initial operation of the back pressure regulating valve BV31 is improved.

(Substrate Processing Apparatus Having Piping Configuration according to Fourth Example)

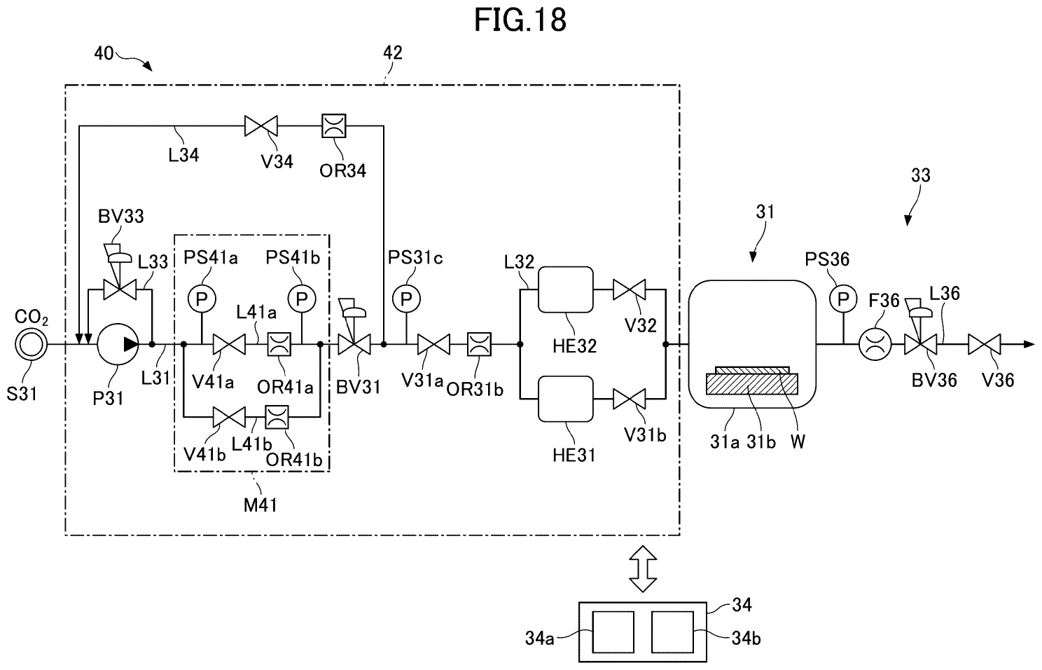

A substrate processing apparatus 40 having a piping configuration according to a fourth example will be described as an example of the substrate processing apparatus 100 with reference to FIG. 18. FIG. 18 is a diagram illustrating the substrate processing apparatus 40 having a piping configuration according to the fourth example.

The substrate processing apparatus 40 differs from the substrate processing apparatus 30 in that the fluid supply device 42 is provided instead of the fluid supply device 32. The other configurations may be the same as those of the substrate processing apparatus 30. Hereinafter, a configuration different from the substrate processing apparatus 30 will be mainly described.

The fluid supply device 42 includes the supply line L31, the branch line L32, the first circulation line L33, and the second circulation line L34.

The supply line L31 is provided with the pump P31, a supply flow measurer M41, the back pressure regulating valve BV31, the pressure sensor PS31c, the opening/closing valve V31a, the orifice OR31b, the heater HE31, and the opening/closing valve V31b in this order from the upstream side.

The supply flow measurer M41 includes a first supply line L41a and a second supply line L41b.

The first supply line L41a is a part of the supply line L41. The first supply line L41a is provided with a pressure sensor PS41a, an opening/closing valve V41a, an orifice OR41a, and a pressure sensor PS41b in this order from the upstream side.

The pressure sensor PS41a and the pressure sensor PS41b may have the same configuration as the pressure sensor PS31a and the pressure sensor PS31b, respectively.

The opening/closing valve V41a is a valve for switching on and off the flow of a processing fluid. The opening/closing valve V41a allows the processing fluid to flow into the secondary side in an open state, and does not allow the processing fluid to flow into the secondary side in a closed state.

The orifice OR41a serves to reduce a flow velocity of and regulate a pressure of the processing fluid flowing through the first supply line L41a. The orifice OR41a allows the pressure-regulated processing fluid to flow into the secondary side. The orifice OR41a is an example of a first orifice.

The second supply line L41b is provided in parallel with the first supply line L41a. The second supply line L41b branches from the first supply line L41a at a point between the pump P31 and the pressure sensor PS41a, and joins the first supply line L41a at a point between the pressure sensor PS41b and the back pressure regulating valve BV31. The second supply line L41b is provided with an opening/closing valve V41b and an orifice OR41b in this order from the upstream side.

The opening/closing valve V41b is provided in parallel with the opening/closing valve V41a. The opening/closing valve V41b is a valve for switching on and off the flow of the processing fluid. The opening/closing valve V41b allows the processing fluid to flow into the secondary side in an open state, and does not allow the processing fluid to flow into the secondary side in a closed state.

The orifice OR41b is provided in parallel with the orifice OR41a. The orifice OR41b serves to reduce a flow velocity of and regulate a pressure of the processing fluid flowing through the second supply line L41b. The orifice OR41b allows the pressure-regulated processing fluid to flow into the secondary side. The orifice OR41b is an example of a second orifice.

As described above, the substrate processing apparatus 40 provides the same effects as the substrate processing apparatus 30.

According to the substrate processing apparatus 40, the second supply line L41b is provided in parallel to the first supply line L41a. The first supply line L41a is provided with an opening/closing valve V41a and an orifice OR41a, and the second supply line L41b is provided with an opening/closing valve V41b and an orifice OR41b. In this case, the regulation range of the supply flow rate of the processing fluid can be increased.

### (Modified Example)

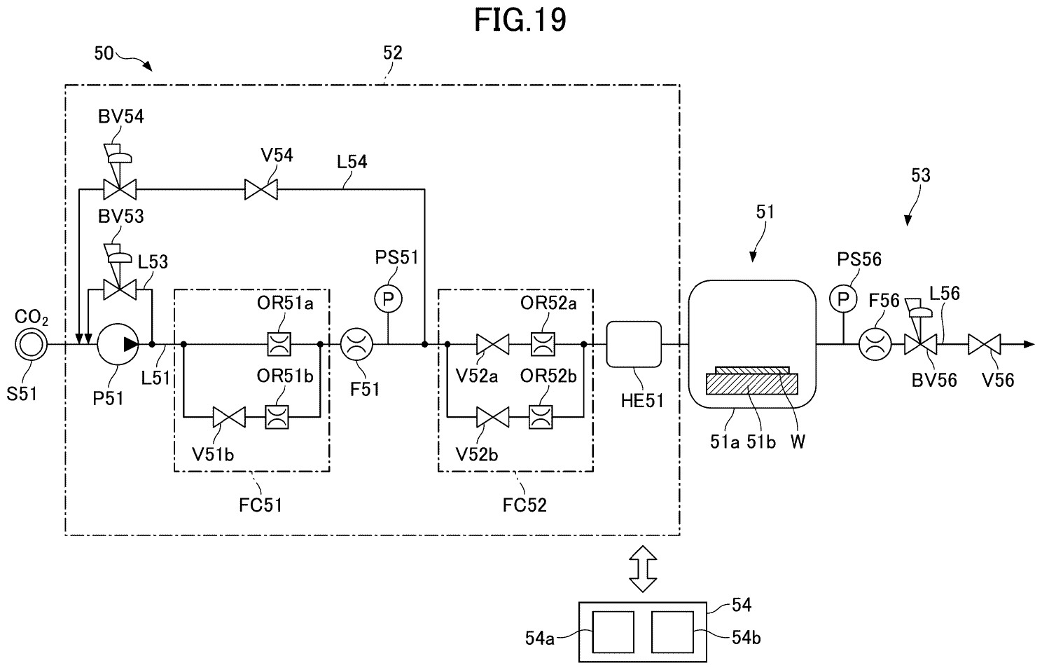

A substrate processing apparatus 50 according to a modified example of the embodiment will be described with reference to FIG. 19. FIG. 19 is a block diagram illustrating the substrate processing apparatus 50 according to the modified example of the embodiment.

The substrate processing apparatus 50 includes a processing device 51, a fluid supply device 52, a discharger 53, and a controller 54.

The processing device 51 may have the same configuration as the processing device 11. The processing device 51 includes a processing vessel 51a and a holder 51b.

The fluid supply device 52 includes a supply line L51, a first circulation line L53, and a second circulation line L54.

The supply line L51 connects the processing fluid supply source S51 and the processing vessel 51a. The supply line L51 supplies a processing fluid from the processing fluid supply source S51 to the processing vessel 51a. The processing fluid is for example carbon dioxide in a gaseous or liquid state. The supply line L51 is provided with a pump P51, a first flow regulator FC51, a flowmeter F51, a pressure sensor PS51, a second flow regulator FC52, and a heater HE51 in this order from the upstream side. A line heater for heating the supply line L51 may be provided in the supply line L51. Opening/closing valves, orifices, filters, temperature sensors, and/or pressures sensors may be further provided at various positions of the supply line L51.

The pump P51 may be configured similarly to the pump P11.

The first flow regulator FC51 regulates the flow rate of the processing fluid flowing through the supply line L51. The first flow regulator FC51 includes an orifice OR51a, an orifice OR51b, and an opening/closing valve V51b.

The orifice OR51a and the orifice OR51b are connected in parallel to each other. The orifice OR51a and the orifice OR51b serve to reduce a flow velocity of and regulate a pressure of the processing fluid flowing through the supply line L51. The orifice OR51a and the orifice OR51b allow the pressure-regulated processing fluid to flow into the secondary side.

The opening/closing valve V51b is connected in series to the orifice OR51b. The opening/closing valve V51b is a valve for switching on and off the flow of the processing fluid. The opening/closing valve V51b allows the processing fluid to flow into the secondary side in an open state, and does not allow the processing fluid to flow into the secondary side in a closed state.

The flowmeter F51 is provided on the secondary side of the first flow regulator FC51. The flowmeter F51 is provided between the first flow regulator FC51 and the second flow regulator FC52 in the supply line L51. The flowmeter F51 may be provided between the second flow regulator FC52 and the heater HE51 in the supply line L51. The flowmeter F51 measures the supply flow rate of the processing fluid flowing through the supply line L51. An output of the flowmeter F51 is transmitted to the controller 54. The flowmeter F51 is, for example, a mass flowmeter.

The pressure sensor PS51 is provided on the secondary side of the flowmeter F51. The pressure sensor PS51 measures the pressure on the secondary side of the first flow regulator FC51. The output of the pressure sensor PS51 is transmitted to the controller 54.

The second flow regulator FC52 regulates the supply flow rate of the processing fluid supplied to the processing vessel 51a. The second flow regulator FC52 includes an opening/closing valve V52a, an opening/closing valve V52b, an orifice OR52a, and an orifice OR52b.

The opening/closing valves V52a and V52b are connected in parallel to each other. The opening/closing valves V52a and V52b are valves for switching on and off of the flow of the processing fluid. The opening/closing valve V52a allows the processing fluid to flow through the orifice OR52a in an open state, and does not allow the processing fluid to flow through the orifice OR52a in a closed state. The opening/closing valve V52b allows the processing fluid to flow through the orifice OR52b in an open state, and does not allow the processing fluid to flow through the orifice OR52b in a closed state.

The orifice OR52a is connected in series to the opening/closing valve V52a. The orifice OR52b is connected in series to the opening/closing valve V52b. The orifice OR52a and the orifice OR52b serve to reduce a flow velocity of and regulate a pressure of the processing fluid flowing through the supply line L51. The orifice OR52a and the orifice OR52b allow the pressure-regulated processing fluid to flow into the secondary side.

The heater HE51 may have the same configuration as the heater HE11.

The first circulation line L53 may have the same configuration as the first circulation line L13. The first circulation line L53 is provided with a back pressure regulating valve BV53. The first circulation line L53 may further include opening/closing valves, orifices, temperature sensors, and/or pressure sensors at various positions.

The back pressure regulating valve BV53 may have the same configuration as the back pressure regulating valve BV13.

The first circulation line L54 branches from the supply line L51 at a point between the pressure sensor PS51 and the second flow regulator FC52, and joins the supply line L51 at a point on the primary side of the pump P51. The second circulation line L54 is provided with an opening/closing valve V54 and a back pressure regulating valve BV54 in this order from the upstream side. The second circulation line L54 may further include opening/closing valves, orifices, temperature sensors, and/or pressure sensors at various positions.

The opening/closing valve V54 is a valve for switching on and off the flow of the processing fluid. The opening/closing valve V54 allows the processing fluid to flow into the secondary side in an open state, and does not allow the processing fluid to flow into the secondary side in a closed state.

In the case where the pressure on the primary side of the second circulation line L54 exceeds a set pressure, the back pressure regulating valve BV54 adjusts its opening degree to allow the processing fluid to flow into the secondary side, so that the pressure of the primary side is maintained at the set pressure. The set pressure of the back pressure regulating valve BV54 is regulated based on, for example, the supply flow rate of the processing fluid measured by the flowmeter F51. The set pressure of the back pressure regulating valve BV54 is regulated by the controller 54, for example.

The discharger 53 may have the same configuration as the discharger 13. The discharger 53 includes a discharge line L56. The discharge line L56 is provided with a pressure sensor PS56, a flowmeter F56, a back pressure regulating valve BV56, and an opening/closing valve V56 in this order from the upstream side.

The controller 54 may have the same configuration as the controller 14. The controller 54 includes an arithmetic calculator 54a and a storage 54b.

The controller 54 receives measurement signals from various sensors (e.g., the pressure sensor PS51, the pressure sensor PS56, the flowmeter F51, and the flowmeter F56), and transmits control signals to various functional elements. The control signals include, for example, opening/closing signals of the opening/closing valves V51b, V52a, V52b, V54, and V56, set pressure signals of the back pressure regulating valves BV53, BV54, and BV56, and a set temperature signal of the heater HE51.

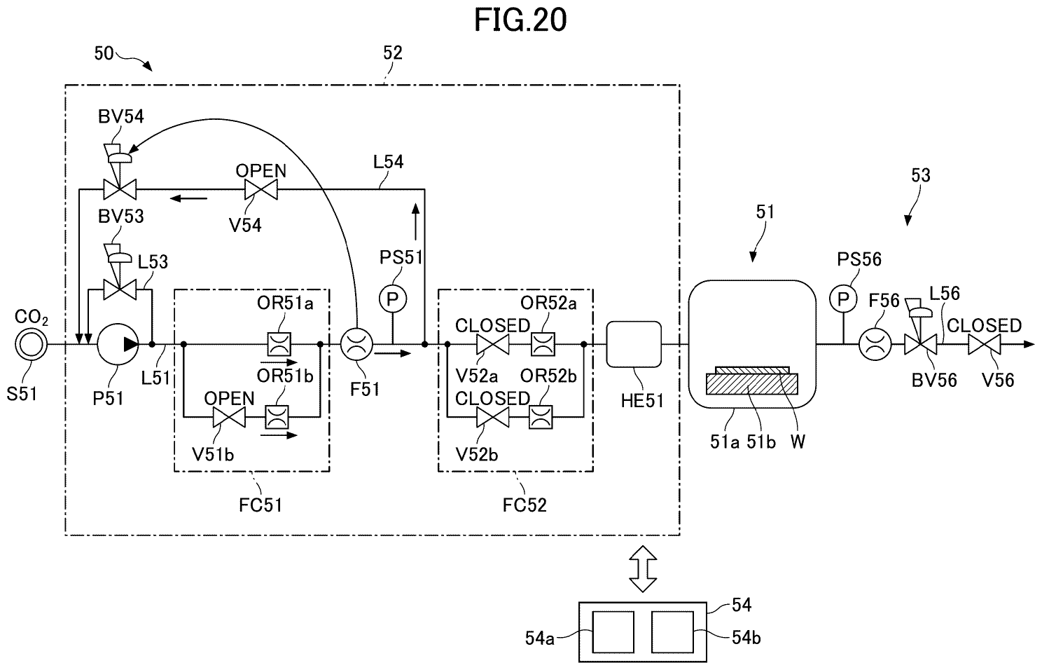

A substrate processing method performed by using the substrate processing apparatus 50 will be described with reference to FIGS. 20 through 24. FIGS. 20 through 24 are diagrams illustrating the operation of the substrate processing apparatus 50 of FIG. 19. The substrate processing method described hereinafter is automatically performed under the control of the controller 54 based on a processing recipe and a control program stored in the storage 54b.

In the description hereinafter, it is assumed that a substrate W is accommodated in the processing vessel 51a in advance. The substrate W subjected to cleaning processing is held by the holder 51b, with the recesses of the pattern on the surface being filled with isopropyl alcohol (IPA).

### <Standby Step>

As illustrated in FIG. 20, in the standby step, the set temperature of the heater HE51 is set to a first temperature, for example, 120° C., the opening/closing valves V51b and V54 are set to an opened state, and the opening/closing valves V52a, V52b, and V56 are set to a closed state. Thus, the processing fluid in the processing fluid supply source S51 circulates through the supply line L51, the second circulation line L54, and the supply line L51 in this order.

During this series of operations, the controller 54 receives the output from the flowmeter F51 and regulates the set pressure of the back pressure regulating valve BV54 so that the supply flow rate of the processing fluid flowing through the primary side of the back pressure regulating valve BV54 becomes a preset flow rate. When a predetermined time elapses after the standby step is started, the standby step is ended, and the first pressure increase step is started.

### <First Pressure Increase Step>

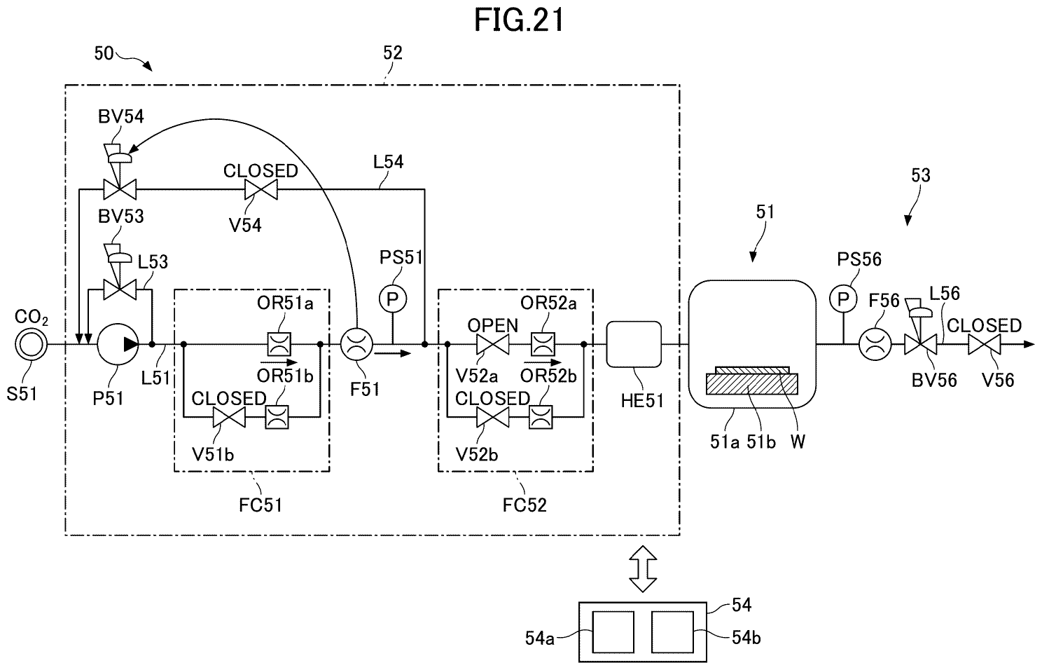

As illustrated in FIG. 21, in the first pressure increase step, the opening/closing valve V52a is switched from a closed state to an open state. Thus, the processing fluid in the processing fluid supply source S51 reaches the heater HE51 via the orifice OR52a, is then heated to the first temperature by the heater HE51, and is thereafter supplied to the processing vessel 51a. Therefore, the processing fluid at the first temperature is supplied to the processing vessel 51a. In the first pressure increase step, the opening/closing valve V51b is switched from an open state to a closed state. In the first pressure increase step, the opening/closing valve V56 is in a closed state, and thus the processing fluid does not flow out from the processing vessel 51a. Therefore, the inner pressure of the processing vessel 51a gradually increases. As a result, pattern collapse can be suppressed. When a predetermined time has elapsed after the first pressure increase step is started, the first pressure increase step is ended, and the second pressure increase step is started.

During this series of operations, the controller 54 receives the output from the flowmeter F51 and regulates the set pressure of the back pressure regulating valve BV54 so that the supply flow rate of the processing fluid flowing through the primary side of the back pressure regulating valve BV54 becomes a preset flow rate.

### <Second Pressure Increase Step>

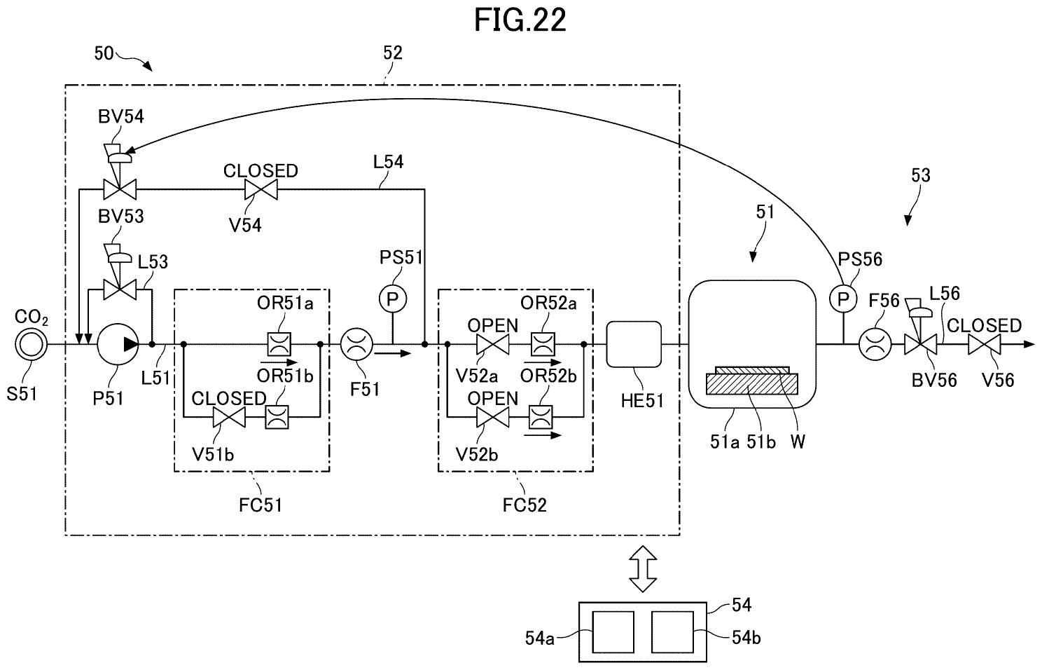

As illustrated in FIG. 22, in the second pressure increase step, the opening/closing valve V52b is switched from a closed state to an open state. Thus, the processing fluid in the processing fluid supply source S51 reaches the heater HE51 via the orifice OR52a and the orifice OR52b, is heated to the first temperature by the heater HE51, and is supplied to the processing vessel 51a. Therefore, the processing fluid at the first temperature is supplied to the processing vessel 51a at a flow rate higher than that in the first pressure increase step. In the second pressure increase step, the opening/closing valve V56 is in a closed state, and thus the processing fluid does not flow out from the processing vessel 51a. Therefore, the inner pressure of the processing vessel 51a gradually increases. In the second pressure increase step, since the pressure of the processing fluid having a larger flow rate than that in the first pressure increase step is increased, the pressure increasing speed is higher than that in the first pressure increase step. Therefore, the time required for the pressure increase can be shortened.

In the second pressure increase step, a pressure of the processing fluid supplied to the processing vessel 51a is lower than a critical pressure. Therefore, the processing fluid is supplied to the processing vessel 51a in a gaseous state. Thereafter, the inner pressure of the processing vessel 51a increases as the filling of the processing vessel 51a with the processing fluid proceeds, and when the inner pressure of the processing vessel 51a exceeds a critical inner pressure, the processing fluid present in the processing vessel 51a becomes at a supercritical state. When the inner pressure of the processing vessel 51a reaches the processing pressure, the second pressure increase step is ended and the distribution step is started. In the second pressure increase step, the opening/closing valve V52b may be switched from a closed state to an open state at a point in time during the pressure increase.

During the series of operations, the controller 54 receives the output from the pressure sensor PS56 and regulates the set pressure of the back pressure regulating valve BV54 in such a manner that the inner pressure of the processing vessel 51a gradually increases at a predetermined rate.

### <Distribution Step>

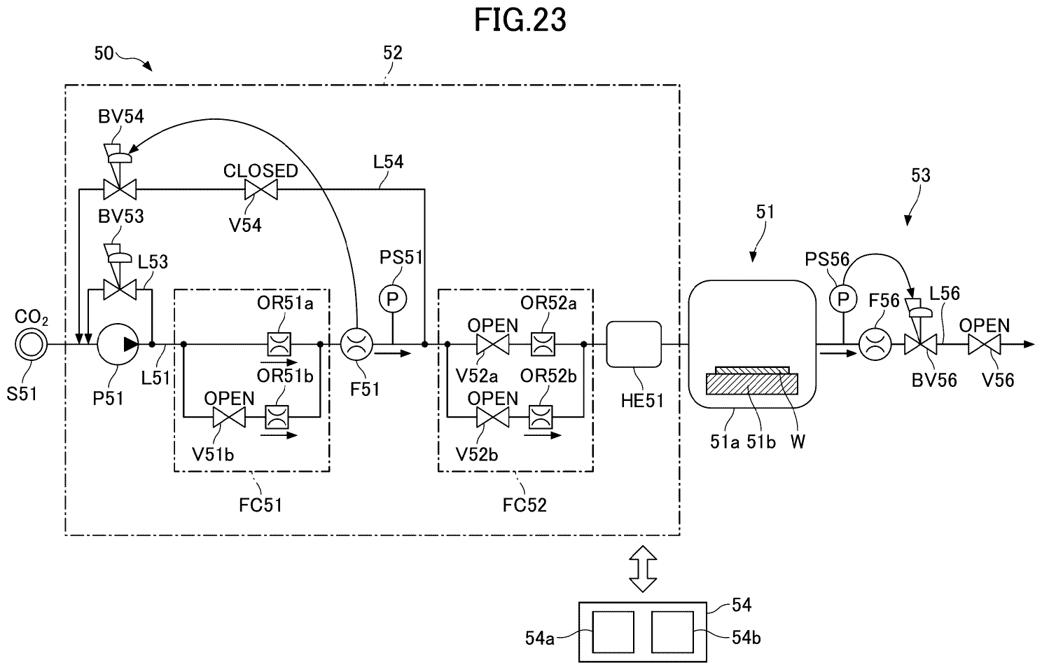

As illustrated in FIG. 23, in the distribution step, the opening/closing valve V56 is switched from a closed state to an open state. Thus, the processing fluid in the processing fluid supply source S51 is supplied to the processing vessel 51a through the supply line L51, and is discharged from the processing vessel 51a through the discharge line L56. In the distribution step, isopropyl alcohol (IPA) in the recesses of the pattern on the substrate W in the processing vessel 51a is replaced with the processing fluid. When the replacement of isopropyl alcohol (IPA) with the processing fluid is completed in the recesses of the pattern, the distribution step is ended and the pressure reduction step is started.

During this series of operations, the controller 54 receives the output from the flowmeter F51 and regulates the set pressure of the back pressure regulating valve BV54 so that the supply flow rate of the processing fluid flowing through the primary side of the back pressure regulating valve BV54 becomes a preset flow rate.

The controller 54 receives the output from the pressure sensor PS56 and regulates the set pressure of the back pressure regulating valve BV56 so as to maintain the pressure in the processing vessel 51a at the processing pressure.

### <Pressure Reduction Step>

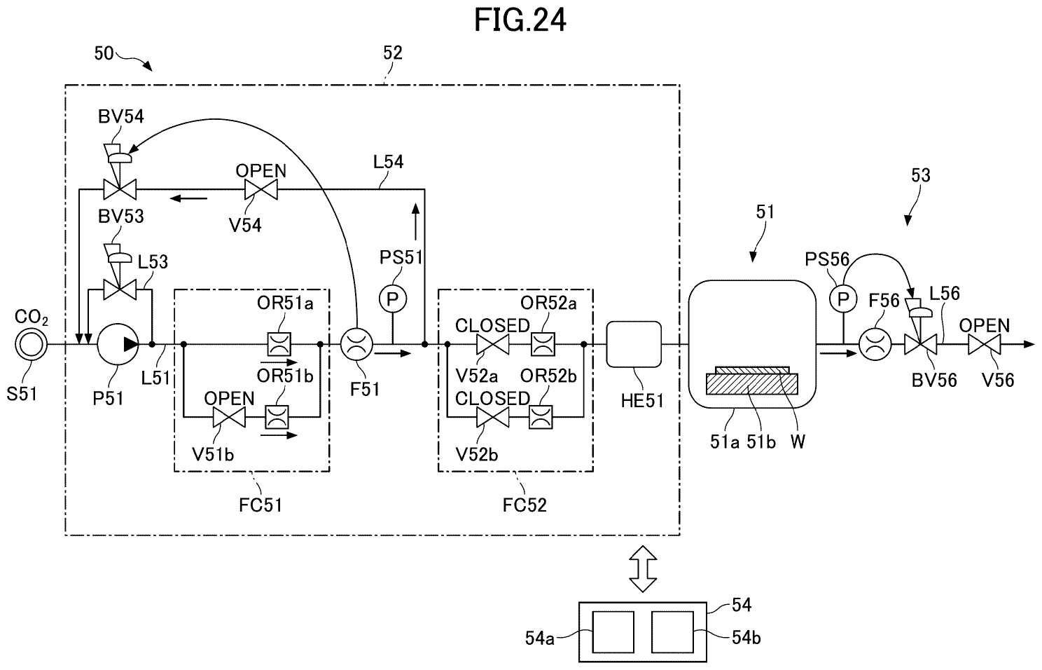

As illustrated in FIG. 24, in the pressure reduction step, the opening/closing valves V52a and V52b are switched from an open state to a closed state. Thus, the processing fluid remaining in the processing vessel 51a is discharged from the discharge line L56. The processing fluid in a supercritical state is vaporized and separated from the surface of the substrate W when the inner pressure of the processing vessel 51a becomes lower than the critical pressure of the processing fluid. Thus, the drying processing for one substrate W is completed. In the pressure reduction step, the opening/closing valve V54 is switched from a closed state to an open state. Thus, the processing fluid in the processing fluid supply source S51 circulates through the supply line L51, the second circulation line L54, and the supply line L51 in this order.

During this series of operations, the controller 54 receives the output from the flowmeter F51 and regulates the set pressure of the back pressure regulating valve BV54 so that the supply flow rate of the processing fluid flowing through the primary side of the back pressure regulating valve BV54 becomes a preset flow rate.

The controller 54 receives the output from the pressure sensor PS56 and regulates the set pressure of the back pressure regulating valve BV56 in such a manner that the inner pressure of the processing vessel 51a gradually changes at a predetermined rate.

As described above, according to the substrate processing apparatus 50, the flowmeter F51 is provided in the supply line L51, and the back pressure regulating valve BV54 is provided in the second circulation line L54. In this case, since the constant pressure valve can be installed at a position away from the supply line, the risk of particles caused by the operation of the constant pressure valve flowing into the supply line can be reduced.

### (Supply Flow Rate Control)

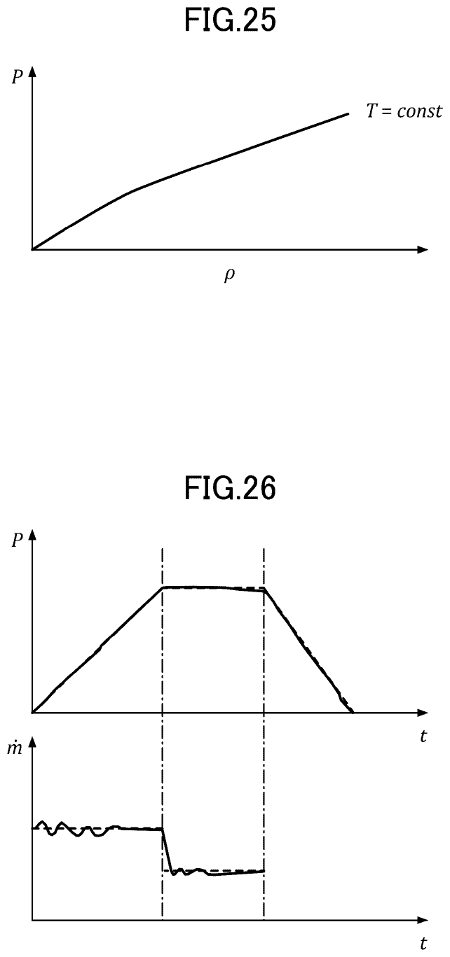

With reference to FIGS. 25 and 26, a description will be given of temporal changes in the mass flow rate of the fluid supplied to the processing space of the processing device 110 and in the pressure in the processing space of the processing device 110 in the case where the controller 140 controls the supply flow regulator 124 based on a supply flow rate of a fluid measured by the supply flow measurer 123.

The mass m of a processing fluid in the processing space at time t when the processing fluid is caused to flow into the processing space of the processing device 110 under a constant supply flow rate is expressed by the following Expression (3). In Expression (3), the mass flow rate is expressed by putting a dot (.) over m, but in the present disclosure, the mass flow rate may be expressed as “m.”.

$$\begin{matrix}[ Mathematical Formula 1 ] & \\ m = \dot{m} t & ( 3 )\end{matrix}$$

From Expression (3), the density of the processing fluid in the processing space at time t is expressed by the following Expression (4).

$$\begin{matrix}[ Mathematical Formula 2 ] & \\ ρ = \frac{m}{V} = \frac{\dot{m}}{V} a & ( 4 )\end{matrix}$$

The relationship between the pressure, density, and temperature of carbon dioxide in a supercritical state is known, and the state of the processing fluid can be calculated using, for example, a Mollier diagram (not illustrated).

Here, since the volume of the processing space is constant, when the temperature (T) of the processing space is constant, the pressure (P) in the processing space is a function of only the density (ρ) as expressed by the following Expression (5).

$$\begin{matrix}[ Mathematical Formula 3 ] & \\ {P}_{( ρ )} & ( 5 )\end{matrix}$$

FIG. 25 shows the relationship between the density and the pressure when the temperature T is constant and the volume of the processing space is constant based on Expression (5). Expression (5) means that the slope of the curve indicating the temporal changes of the pressure in the processing space correlates with the mass flow rate of the fluid flowing into the processing space. As shown in FIG. 25, the pressure smoothly increases with the increase in density. In other words, by controlling the mass flow rate of the fluid flowing into the processing space to be constant, the pressure value of the processing space can be smoothly increased. Thus, the accuracy of the flow rate control of the processing fluid supplied to the processing device 110 can be improved.

FIG. 26 is graphs showing temporal changes in the pressure P in the processing space and the mass flow rate m. of a fluid. The upper part of FIG. 26 is a graph showing temporal changes in the pressure P in the processing space. In the upper graph of FIG. 26, the horizontal axis represents time t, and the vertical axis represents the pressure P in the processing space. In the upper graph of FIG. 26, the solid line indicates an actual measurement value of the pressure P of the processing space, and the broken line indicates a target value of the pressure P of the processing space. The lower graph of FIG. 26 is a graph showing the mass flow rate m. of the fluid flowing into the processing space. In the lower graph of FIG. 26, the horizontal axis represents time t, and the vertical axis represents the mass flow rate m. of the fluid flowing into the processing space. In the lower graph of FIG. 26, the solid line represents an actual measurement value of the mass flow rate m. of the fluid flowing into the processing space, and the broken line represents a target value of the mass flow rate m. of the fluid flowing into the processing space.

As shown in the lower graph of FIG. 26, by controlling the mass flow rate m. of the fluid flowing into the processing space to be substantially constant, the pressure in the processing space is linearly changed along the target value as illustrated in the upper graph of FIG. 26. Therefore, for example, the pressure in the processing space can be smoothly controlled during the pressure increase.

In contrast, consider a case where the supply flow regulator 124 is controlled based on the pressure of the processing space. The pressure in the processing space changes with respect to time as illustrated in the upper graph of FIG. 26. Therefore, the responsiveness in the case of controlling the supply flow regulator 124 is poor, and it is difficult to smoothly change the pressure of the processing space.

The embodiments disclosed herein are merely an example in all respects and should not be construed as being limited thereto. The above-described embodiments may be omitted, replaced, and modified in various forms without departing from the scope and spirit of the appended claims.

What is claimed is:

1. A substrate processing apparatus, comprising:
a processing device that has a processing space capable of accommodating a substrate whose surface is wet with a liquid;
a fluid supply device configured to supply a processing fluid to the processing space; and
a controller, wherein
the fluid supply device includes
a supply line connected to the processing device,
a pressurizer provided in the supply line and configured to increase a pressure of the processing fluid flowing through the supply line,
a supply flow measurer provided on a secondary side of the pressurizer in the supply line, and
a supply flow regulator provided on a secondary side of the supply flow measurer in the supply line, and
the controller controls the supply flow regulator based on a supply flow rate of the processing fluid measured by the supply flow measurer.

2. The substrate processing apparatus according to claim 1, wherein
the supply flow measurer includes
a first orifice configured to reduce a flow velocity of the processing fluid,
a first pressure sensor provided on a primary side of the first orifice, and
a second pressure sensor provided on a secondary side of the first orifice, wherein
the supply flow measurer calculates the supply flow rate of the processing fluid based on a difference between a first pressure measured by the first pressure sensor and a second pressure measured by the second pressure sensor.

3. The substrate processing apparatus according to claim 1, wherein
the controller is configured to perform (a) standing-by while circulating the processing fluid in the fluid supply device without supplying the processing fluid to the processing space, and
the controller is configured to control, in (a), the supply flow regulator based on the supply flow rate of the processing fluid measured by the supply flow measurer.

4. The substrate processing apparatus according to claim 1, wherein
the controller is configured to perform (b) discharging the processing fluid in the supply line, and
the controller is configured to control, in (b), the supply flow regulator based on the supply flow rate of the processing fluid measured by the supply flow measurer.

5. The substrate processing apparatus according to claim 1, wherein
the controller is configured to perform (c) increasing a pressure in the processing space by circulating the processing fluid in the fluid supply device and supplying the processing fluid from the fluid supply device to the processing space, wherein
the controller is configured to control, in (c), the supply flow regulator based on the supply flow rate of the processing fluid measured by the supply flow measurer.

6. The substrate processing apparatus according to claim 1, wherein
the controller is configured to perform (d) increasing a pressure in the processing space to a processing pressure by supplying the processing fluid from the fluid supply device to the processing space, and
the controller is configured to control, in (d), the supply flow regulator based on the pressure of the processing space.

7. The substrate processing apparatus according to claim 1, further comprising:
a discharger configured to discharge the processing fluid from the processing space, wherein
the discharger includes a pressure regulator configured to regulate a pressure in the processing space,
the controller is configured to perform (e) supplying the processing fluid from the fluid supply device to the processing space and discharging the processing fluid in the processing space from the discharger, and
the controller is configured to control, in (e), the supply flow regulator based on the supply flow rate of the processing fluid measured by the supply flow measurer, and control the pressure regulator based on the pressure of the processing space.

8. The substrate processing apparatus according to claim 1, further comprising:
a discharger configured to discharge the processing fluid from the processing space, wherein
the discharger includes a pressure regulator configured to regulate a pressure in the processing space,
the controller is configured to perform (f) stopping supplying the processing fluid from the fluid supply device to the processing space and discharging the processing fluid in the processing space from the discharger, and
the controller is configured to control, in (f), the supply flow regulator based on the supply flow rate of the processing fluid measured by the supply flow measurer, and control the pressure regulator based on the pressure of the processing space.

9. The substrate processing apparatus according to claim 3, wherein
the fluid supply device includes
a heater provided on a secondary side of the supply flow regulator in the supply line and configured to heat the processing fluid flowing through the supply line,
an opening/closing valve provided on a secondary side of the heater in the supply line, and
a circulation line that branches from the supply line at a point between the heater and the opening/closing valve and joins the supply line at a point on a primary side of the pressurizer.

10. The substrate processing apparatus according to claim 9, wherein
(a) includes flowing the processing fluid through the heater.

11. The substrate processing apparatus according to claim 1, wherein
the fluid supply device includes a pressure regulator provided on a primary side of the supply flow regulator in the supply line and configured to maintain a pressure on the primary side of the supply flow regulator at a set pressure.

12. The substrate processing apparatus according to claim 2, wherein
the controller is configured to perform (a) standing-by while circulating the processing fluid in the fluid supply device without supplying the processing fluid to the processing space, and
the controller is configured to control, in (a), the supply flow regulator based on the supply flow rate of the processing fluid measured by the supply flow measurer.

13. The substrate processing apparatus according to claim 2, wherein
the controller is configured to perform (b) discharging the processing fluid in the supply line, and
the controller is configured to control, in (b), the supply flow regulator based on the supply flow rate of the processing fluid measured by the supply flow measurer.

14. The substrate processing apparatus according to claim 2, wherein
the controller is configured to perform (c) increasing a pressure in the processing space by circulating the processing fluid in the fluid supply device and supplying the processing fluid from the fluid supply device to the processing space, wherein
the controller is configured to control, in (c), the supply flow regulator based on the supply flow rate of the processing fluid measured by the supply flow measurer.

15. The substrate processing apparatus according to claim 2, wherein
the controller is configured to perform (d) increasing a pressure in the processing space to a processing pressure by supplying the processing fluid from the fluid supply device to the processing space, and
the controller is configured to control, in (d), the supply flow regulator based on the pressure of the processing space.

16. The substrate processing apparatus according to claim 2, further comprising:
a discharger configured to discharge the processing fluid from the processing space, wherein
the discharger includes a pressure regulator configured to regulate a pressure in the processing space,
the controller is configured to perform (e) supplying the processing fluid from the fluid supply device to the processing space and discharging the processing fluid in the processing space from the discharger, and
the controller is configured to control, in (e), the supply flow regulator based on the supply flow rate of the processing fluid measured by the supply flow measurer, and control the pressure regulator based on the pressure of the processing space.

17. The substrate processing apparatus according to claim 2, further comprising:
a discharger configured to discharge the processing fluid from the processing space, wherein
the discharger includes a pressure regulator configured to regulate a pressure in the processing space,
the controller is configured to perform (f) stopping supplying the processing fluid from the fluid supply device to the processing space and discharging the processing fluid in the processing space from the discharger, and
the controller is configured to control, in (f), the supply flow regulator based on the supply flow rate of the processing fluid measured by the supply flow measurer, and control the pressure regulator based on the pressure of the processing space.

18. The substrate processing apparatus according to claim 12, wherein
the fluid supply device includes
a heater provided on a secondary side of the supply flow regulator in the supply line and configured to heat the processing fluid flowing through the supply line,
an opening/closing valve provided on a secondary side of the heater in the supply line, and
a circulation line that branches from the supply line at a point between the heater and the opening/closing valve and joins the supply line at a point on a primary side of the pressurizer.

19. The substrate processing apparatus according to claim 18, wherein
(a) includes flowing the processing fluid through the heater.

20. A substrate processing apparatus, comprising:
a processing device that has a processing space capable of accommodating a substrate whose surface is wet with a liquid;
a fluid supply device configured to supply a processing fluid to the processing space; and
a controller, wherein
the fluid supply device includes
a supply line connected to the processing device,
a pressurizer provided in the supply line and configured to increase a pressure of the processing fluid flowing through the supply line,
a mass flowmeter provided on a secondary side of the pressurizer in the supply line,
a circulation line that branches from the supply line at a point on a secondary side of the pressurizer in the supply line and joins the supply line at a point on a primary side of the pressurizer, and
a supply flow regulator provided in the circulation line, and
the controller controls the supply flow regulator based on a supply flow rate of the processing fluid measured by the mass flowmeter.
